(19) United States
(12) Patent Application Publication
(10) Pub. No.: US 2025/0199404 A1
(43) Pub. Date: Jun. 19, 2025

(54) ACTINIC RAY-SENSITIVE OR RADIATION-SENSITIVE RESIN COMPOSITION, RESIST FILM, PATTERN FORMING METHOD, AND METHOD FOR PRODUCING ELECTRONIC DEVICE

(71) Applicant: FUJIFILM CORPORATION, Tokyo (JP)

(72) Inventors: Takeshi Kawabata, Shizuoka (JP); Aina Shibuya, Shizuoka (JP); Masafumi Kojima, Shizuoka (JP); Akiyoshi Goto, Shizuoka (JP)

(21) Appl. No.: 19/064,975

(22) Filed: Feb. 27, 2025

Related U.S. Application Data
(63) Continuation of application No. PCT/JP2023/030783, filed on Aug. 25, 2023.

(30) Foreign Application Priority Data
Aug. 31, 2022 (JP) 2022-138715

(51) Int. Cl. G03F 7/039; C08F 212/14; C08F 220/06; C08F 220/22; C08F 220/58; C08F 230/10; C08K 5/00; C08K 5/57

(52) U.S. Cl. CPC G03F 7/039; C08F 212/24; C08F 220/06; C08F 220/22; C08F 220/585; C08F 230/10; C08K 5/0091; C08K 5/57

(57) ABSTRACT

Provided are an actinic ray-sensitive or radiation-sensitive resin composition containing a resin including a specific repeating unit represented by formula (1) and a specific repeating unit represented by formula (2), at least one of the repeating unit represented by formula (1) or the repeating unit represented by formula (2) having a group derived from at least one metal compound selected from the group consisting of a metal complex, an organometallic salt, an inorganic metal compound, and an organometallic compound, a resist film formed from the actinic ray-sensitive or radiation-sensitive resin composition, a pattern forming method that uses the actinic ray-sensitive or radiation-sensitive resin composition, and a method for producing an electronic device.

### CROSS REFERENCE TO RELATED APPLICATION

This is a continuation of International Application No. PCT/JP2023/030783 filed on Aug. 25, 2023, and claims priority from Japanese Patent Application No. 2022-138715 filed on Aug. 31, 2022, the entire disclosure of which is incorporated herein by reference.

### BACKGROUND OF THE INVENTION

### 1. Field of the Invention

The present invention relates to an actinic ray-sensitive or radiation-sensitive resin composition, a resist film, a pattern forming method, and a method for producing an electronic device.

### 2. Description of the Related Art

Since the advent of a resist for KrF excimer laser (248 nm), pattern forming methods utilizing chemical amplification have been used in order to compensate for a decrease in sensitivity due to light absorption. For example, in a positive chemical amplification method, first, a photoacid generator contained in exposed portions is decomposed upon photoirradiation to generate an acid. Subsequently, in a post exposure bake (PEB) process or the like, for example, an alkali-insoluble group of a resin included in an actinic ray-sensitive or radiation-sensitive resin composition is turned into an alkali-soluble group by the catalytic action of the generated acid to change the solubility in a developer. Development is then performed using, for example, a basic aqueous solution. As a result, the exposed portions are removed to obtain a desired pattern.

Also known are pattern forming methods using a polymer whose main chain undergoes scission upon irradiation with an actinic ray or a radiation.

For example, JP2002-196494A and WO2020/170555A disclose a resin that can undergo a molecular weight decrease as a result of scission of the main chain upon irradiation with an electron beam and that has a repeating unit including a tin atom.

JP2001-72716A discloses a resin that can undergo a molecular weight decrease as a result of scission of the main chain upon irradiation with an electron beam and that has a repeating unit including a ferrocene structure.

### SUMMARY OF THE INVENTION

For miniaturization of semiconductor devices, the wavelengths of exposure light sources have been shortened and the numerical apertures (NAs) of projector lenses have been increased, and exposure devices using ArF excimer laser having a wavelength of 193 nm as a light source have now been developed. In addition, pattern forming methods using extreme ultraviolet rays (EUV light) and an electron beam (EB) as a light source have also recently been studied. Under such circumstances, further improvement in performance of an actinic ray-sensitive or radiation-sensitive resin composition is demanded.

The present inventors prepared an actinic ray-sensitive or radiation-sensitive resin composition including a desired polymer with reference to JP2002-196494A and JP2001-72716A and conducted studies, and it turned out that its sensitivity did not reach the level required nowadays, leaving room for further improvement.

Thus, an object of the present invention is to provide an actinic ray-sensitive or radiation-sensitive resin composition having high sensitivity.

Another object of the present invention is to provide a resist film formed of the actinic ray-sensitive or radiation-sensitive resin composition, a pattern forming method using the actinic ray-sensitive or radiation-sensitive resin composition, and a method for producing an electronic device.

The present inventors have found that the above objects can be achieved by the following configurations.

[1]

An actinic ray-sensitive or radiation-sensitive resin composition containing a resin including a repeating unit represented by formula (1) below and a repeating unit represented by formula (2) below.

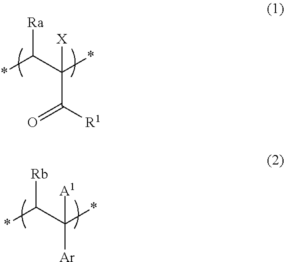

In formula (1), X represents a halogen atom, a fluorinated alkyl group, or a fluorinated cycloalkyl group.

Ra represents a hydrogen atom or a substituent.

R¹ represents a substituent. R¹ and Ra may be bonded to each other to form a ring.

In formula (2), A¹ represents an optionally substituted alkyl group or cycloalkyl group.

Rb represents a hydrogen atom or a substituent.

Ar represents an aromatic hydrocarbon group or a metal complex group.

Ar and Rb may be bonded to each other to form a ring.

At least one of the repeating unit represented by formula (1) or the repeating unit represented by formula (2) has a group derived from at least one metal compound selected from the group consisting of a metal complex, an organometallic salt, an inorganic metal compound, and an organometallic compound.

[2]

The actinic ray-sensitive or radiation-sensitive resin composition according to [1], wherein the resin includes at least one functional group selected from the group consisting of a hydroxyl group, a carboxyl group, an amino group, an amide group, an imide group, a thiol group, an acetyl group, and an acetoxy group.

[3]

The actinic ray-sensitive or radiation-sensitive resin composition according to [1] or [2], wherein the resin includes at least one functional group selected from the group consisting of a phenolic hydroxyl group and a carboxyl group.

[4]

The actinic ray-sensitive or radiation-sensitive resin composition according to any one of [1] to [3], wherein X in formula (1) above represents a chlorine atom.

[5]

The actinic ray-sensitive or radiation-sensitive resin composition according to any one of [1] to [4], wherein the group derived from the at least one metal compound includes at least one metal atom selected from the group consisting of an iron atom, a titanium atom, a tin atom, a selenium atom, a zirconium atom, a zinc atom, a bismuth atom, a germanium atom, and a hafnium atom.

[6]

The actinic ray-sensitive or radiation-sensitive resin composition according to any one of [1] to [5], further including a photodecomposable onium salt compound.

[7]

The actinic ray-sensitive or radiation-sensitive resin composition according to any one of [1] to [6], further having at least one metal compound selected from the group consisting of a metal complex, an organometallic salt, and an organometallic compound.

[8]

A resist film formed from the actinic ray-sensitive or radiation-sensitive resin composition according to any one of [1] to [7].

[9]

A pattern forming method including:
forming a resist film on a substrate using the actinic ray-sensitive or radiation-sensitive resin composition according to any one of [1] to [7];
exposing the resist film; and
developing the exposed resist film using a developer.
   [10]

A method for producing an electronic device, the method including the pattern forming method according to [9].

According to the present invention, an actinic ray-sensitive or radiation-sensitive resin composition having high sensitivity, a resist film, a pattern forming method, and a method for producing an electronic device, the method including the pattern forming method, can be provided.

### DESCRIPTION OF THE PREFERRED EMBODIMENTS

Hereinafter, the present invention will be described in detail.

It should be appreciated that although the following description of constituent features may be made in the context of a representative embodiment of the present invention, the present invention is not limited to the embodiment.

Regarding expressions of groups (atomic groups) in the present specification, an expression not specified as substituted or unsubstituted encompasses a group having no substituents and also a group having a substituent without departing from the spirit of the present invention. For example, an “alkyl group” encompasses not only an alkyl group having no substituents (an unsubstituted alkyl group) but also an alkyl group having a substituent (a substituted alkyl group). The term “organic group” in the present specification refers to a group including at least one carbon atom.

The substituent is preferably a monovalent substituent unless otherwise specified.

The term “actinic ray” or “radiation” in the present specification means, for example, an emission line spectrum of a mercury lamp, far ultraviolet rays represented by excimer lasers, extreme ultraviolet rays (EUV), X rays, or an electron beam (EB). The term “light” in the present specification means an actinic ray or a radiation.

The term “exposure” in the present specification includes, unless otherwise specified, not only exposure with, for example, an emission line spectrum of a mercury lamp, far ultraviolet rays represented by excimer lasers, extreme ultraviolet rays, X-rays, or EUV light but also patterning with a corpuscular beam such as an electron beam or an ion beam.

In the present specification, the term “to” is used to mean that numerical values given before and after “to” are included as lower and upper limit values.

The bonding direction of a divalent group given in the present specification is not limited unless otherwise specified. For example, in a compound represented by a formula “X⁻Y—Z” where Y is —COO—, Y may be —CO—O— or —O—CO—. This compound may be represented as “X—CO—O—Z” or “X—O—CO—Z”.

In the present specification, a weight-average molecular weight (Mw), a number-average molecular weight (Mn), and a dispersity (also referred to as a molecular weight distribution) (Mw/Mn) of a resin are defined as polystyrene equivalent values determined using a gel permeation chromatography (GPC) apparatus (HLC-8120GPC manufactured by Tosoh Corporation) by GPC measurement (solvent: tetrahydrofuran, flow rate (sample injection volume): 10 μL, column: TSK gel Multipore HXL-M manufactured by Tosoh Corporation, column temperature: 40° C., flow rate: 1.0 mL/min, detector: differential refractive index detector.

In the present specification, examples of halogen atoms include a fluorine atom, a chlorine atom, a bromine atom, and an iodine atom.

In the present specification, the term “solid content” means a component forming a resist film and does not include solvents. Any component forming a resist film is regarded as a solid content even in the form of liquid.

### Actinic Ray-Sensitive or Radiation-Sensitive Resin Composition

An actinic ray-sensitive or radiation-sensitive resin composition according to the present invention is an actinic ray-sensitive or radiation-sensitive resin composition containing a resin including a repeating unit represented by formula (1) below and a repeating unit represented by formula (2) below.

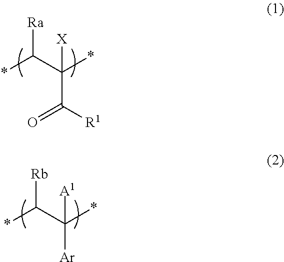

In formula (1), X represents a halogen atom, a fluorinated alkyl group, or a fluorinated cycloalkyl group.

Ra represents a hydrogen atom or a substituent.

R¹ represents a substituent. R¹ and Ra may be bonded to each other to form a ring.

In formula (2), A¹ represents an optionally substituted alkyl or cycloalkyl group.

Rb represents a hydrogen atom or a substituent.

Ar represents an aromatic hydrocarbon group or a metal complex group. Ar and Rb may be bonded to each other to form a ring.

At least one of the repeating unit represented by formula (1) or the repeating unit represented by formula (2) has a group derived from at least one metal compound selected from the group consisting of a metal complex, an organometallic salt, an inorganic metal compound, and an organometallic compound.

The actinic ray-sensitive or radiation-sensitive resin composition according to the present invention is typically a resist composition. Hereinafter, the actinic ray-sensitive or radiation-sensitive resin composition according to the present invention is also referred to as the “resist composition”.

The resist composition according to the present invention has high sensitivity due to the above configuration. While the reasons for this are not fully understood, the present inventors presume as follows.

The resin included in the resist composition according to the present invention, because of having a repeating unit represented by formula (1) and a repeating unit represented by formula (2), undergoes scission of the main chain upon irradiation with an actinic ray or a radiation to have a decreased molecular weight, resulting in an increase in solubility in a developer. When a resist film formed of the resist composition including this specific resin is irradiated with an actinic ray or a radiation, a difference in solubility in a developer (dissolution contrast) between exposed portions and unexposed portions is caused by the above mechanism of action of the specific resin, thus enabling the formation of a pattern.

The specific resin has a group including a metallic element in at least one of the repeating unit represented by formula (1) or the repeating unit represented by formula (2) which can undergo main chain scission upon irradiation with an actinic ray or a radiation. By having a group including a metallic element with a high electron density, the amount of generation of secondary electrons upon irradiation with an actinic ray or a radiation is increased as compared to when having a group including no metallic elements. It is presumed that since this generation of secondary electrons occurs in a repeating unit that can undergo main chain scission, the generated secondary electrons efficiently contribute to the main chain scission, leading to higher sensitivity.

In the following, the case where the resist composition has higher sensitivity is also referred to as “the advantageous effect of the present invention is better produced”.

Hereinafter, various components included in the resist composition will first be described.

### Resin (B)

The resist composition according to the present invention includes a specific resin (also referred to as a “resin (B)”) including a repeating unit represented by formula (1) above and a repeating unit represented by formula (2) above. The resin (B) has, in at least one of the repeating unit represented by formula (1) or the repeating unit represented by formula (2), a group derived from at least one metal compound selected from the group consisting of a metal complex, an organometallic salt, an inorganic metal compound, and an organometallic compound.

The resin (B), by virtue of including the repeating unit represented by formula (1) above and the repeating unit represented by formula (2) above, functions as a so-called main-chain scission-type polymer whose main chain undergoes scission upon irradiation with an actinic ray or a radiation. The resin (B) is preferably a resin whose main chain is decomposed upon irradiation with X⁻rays, an electron beam, or extreme ultraviolet rays, more preferably a resin whose main chain is decomposed upon irradiation with an electron beam or extreme ultraviolet rays.

The resin (B) may be a random copolymer, a block copolymer, or an alternating copolymer.

### Metal-Containing Group

First, the group derived from at least one metal compound selected from the group consisting of a metal complex, an organometallic salt, an inorganic metal compound, and an organometallic compound (hereinafter also referred to simply as the “metal-containing group”), the group being included in at least one of the repeating unit represented by formula (1) or the repeating unit represented by formula (2), will be described.

As described above, the resin (B), by virtue of including the metal-containing group in at least one of the repeating unit represented by formula (1) or the repeating unit represented by formula (2), provides the resist composition according to the present invention with high sensitivity. The presence of the metal-containing group in the resin (B) is preferred also from the viewpoint of etching resistance.

Examples of the metal-containing group include monovalent groups derived by removing any one hydrogen atom from the metal compounds given below and divalent groups derived by removing any two hydrogen atoms. The metal-containing group may be a monovalent group derived by removing any one substituent or ligand bonded to a metal atom from any of the metal compounds given below.

Examples of the metal atom included in the metal compound include a lithium atom, a sodium atom, a magnesium atom, an aluminum atom, a potassium atom, a calcium atom, a scandium atom, a titanium atom, a vanadium atom, a chromium atom, a manganese atom, an iron atom, a cobalt atom, a nickel atom, a copper atom, a zinc atom, a gallium atom, a rubidium atom, a strontium atom, an yttrium atom, a zirconium atom, a ruthenium atom, a rhodium atom, a palladium atom, a silver atom, a cadmium atom, an indium atom, a tin atom, an antimony atom, a tellurium atom, a cesium atom, a barium atom, a hafnium atom, a tungsten atom, a rhenium atom, an osmium atom, an iridium atom, a platinum atom, a gold atom, a mercury atom, a thallium atom, a lead atom, a bismuth atom, a lanthanum atom, a cerium atom, a praseodymium atom, a neodymium atom, a samarium atom, a europium atom, a gadolinium atom, a terbium atom, a dysprosium atom, a holmium atom, an erbium atom, a thulium atom, an ytterbium atom, and a lutetium atom.

For even higher sensitivity, the metal compound preferably includes, particularly, at least one atom selected from the group consisting of an iron atom, a titanium atom, a tin atom, a cobalt atom, a nickel atom, a selenium atom, a zirconium atom, a zinc atom, a silver atom, an indium atom, a bismuth atom, a germanium atom, and a hafnium atom, more preferably includes at least one atom selected from the group consisting of an iron atom, a titanium atom, a tin atom, a selenium atom, a zirconium atom, a zinc atom, a bismuth atom, a germanium atom, and a hafnium atom.

The metal complex is, for example, a metal complex including a central metal atom (preferably, a transition metal atom or a main group metal atom such as zinc) and ligands (e.g., neutral or anionic unidentate ligands or neutral or anionic polydentate ligands (preferably bidentate ligands)) coordinating to the central metal atom. In particular, the metal complex is preferably a metal complex including a central metal atom and organic ligands coordinating to the central metal atom. Here, the term “organic ligand” refers to a ligand including at least one carbon atom.

At least one of the ligands in the metal complex is also preferably an organic ligand.

Examples of the central metal atom include the metal atoms given above. Among them, for example, an iron atom, a titanium atom, a zirconium atom, and a hafnium atom are preferred.

Examples of the bond between the central metal atom and the ligands include a metal-nitrogen bond, a metal-carbon bond, a metal-oxygen bond, a metal-phosphorus bond, a metal-sulfur bond, and a metal-halogen bond.

Examples of the ligands included in the metal complex include halogen atoms, alkyl groups, cycloalkyl groups, acyl groups (e.g., an acetylacetonato group), a carbonyl group, an isocyanide group, alkene groups (e.g., a butadiene group and a cyclooctadiene group), alkyne groups, aryl groups (e.g., benzene and naphthalene), alkylidene groups, alkylidyne groups, a cyclopentadienyl group, an indenyl group, a cycloheptatrienium group, a cyclobutadiene group, molecular nitrogen, a nitro group, a phosphene group, a phosphine group, a thiol group, a hydroxyl group, an amine group, an ether group, alkoxide groups, an amide group, and a silyl group.

The organometallic salt is, for example, a salt composed of a metal ion and a counter ion, provided that either the metal ion or the counter ion includes at least one carbon atom.

The metal ion may be an organic metal ion or an inorganic metal ion. Here, the term “organic metal ion” refers to an ion including at least one carbon atom and a metal atom.

The counter ion may be an inorganic counter ion or an organic counter ion. Here, the term “organic counter ion” refers to a counter ion including at least one carbon atom.

Examples of the inorganic metal ion include metal ions of the above-described metal atom species.

Examples of the organic metal ion include, but are not limited to, metal ions including a carbon atom and a metal atom selected from the group consisting of a selenium atom and an antimony atom.

Specifically, for example, an organic metal ion represented by formula (1M) or (2M) below is preferred.

Se⁺(R^{M1})(R^{M2})(R^{M3}) Formula (1M):

Sb⁺(R^{M4})(R^{M5})(R^{M6})(R^{M7}) Formula (2M):

In formula (1M), R^{M1} to R^{M3} each represent an organic group.

In formula (2M), R^{M4} to R^{M7} each represent an organic group.

Examples of the organic groups represented by R^{M1} to R^{M7} in formulas (1M) and (2M) include organic groups W described later, among which aryl groups are preferred, and a phenyl group is more preferred.

Examples of the inorganic counter ion include, but are not limited to, phosphate anions (e.g., a hexafluorophosphate anion).

Examples of the organic counter ion include, but are not limited to, quaternary nitrogen-containing organic cations (e.g., a pyridinium ion), sulfonate anions (such as aliphatic sulfonate anions and aromatic sulfonate anions (e.g., a perfluoromethyl sulfonate anion)), and carboxylate anions (such as aliphatic carboxylate anions and aromatic carboxylate anions (e.g., a 2-pyridine carboxylate anion)).

Examples of the inorganic metal compound include metal hydroxides (e.g., zinc hydroxide).

Examples of the organometallic compound include compounds including at least one metal-carbon bond (particularly, metal-carbon covalent bond). Examples of the metal atom included in the organometallic compound include a tin atom, a germanium atom, a bismuth atom, and a tellurium atom. In one embodiment, the organometallic compound may be an organotin compound, for example, a compound represented by formula (1S) or (2S) below.

Sn(R^{S1})ₚ(R^{S2})_{q} Formula (1S):

In formula (1S), R^{S1} represents an alkyl group, a cycloalkyl group, an alkenyl group, a cycloalkenyl group, an alkynyl group, a cycloalkynyl group, or an aryl group.

Examples of the alkyl group, the cycloalkyl group, the alkenyl group, the cycloalkenyl group, the alkynyl group, the cycloalkynyl group, and the aryl group represented by R^{S1} include alkyl groups, cycloalkyl groups, alkenyl groups, cycloalkenyl groups, alkynyl groups, cycloalkynyl groups, and aryl groups given as examples of the organic group W described later.

R^{S2} represents an alkylcarbonyloxy group or a mono- or dialkylamino group. Here, the mono- or dialkylamino group means a group derived by substituting one or two hydrogen atoms of an amino group with alkyl groups.

Examples of the alkyl moiety in the alkylcarbonyloxy group and the alkyl moiety in the mono- or dialkylamino group are the same as those of the alkyl group represented by R^{S1}.

The alkylcarbonyloxy group is, for example, an acetoxy group.

The mono- or dialkylamino group is, for example, a diethylamino group.

In formula (1S), p represents an integer of 1 to 4, q represents an integer of 0 to 3, and p+q=4 is satisfied.

In formula (1S), p particularly preferably represents 1 or 2.

R^{S3}—Sn(═O)—OH Formula (2S):

In formula (2S), R^{S3} represents an alkyl group, a cycloalkyl group, an alkenyl group, a cycloalkenyl group, an alkynyl group, a cycloalkynyl group, or an aryl group.

Examples of the alkyl group, the cycloalkyl group, the alkenyl group, the cycloalkenyl group, the alkynyl group, the cycloalkynyl group, and the aryl group represented by R^{S3} are the same as those of the alkyl group, the cycloalkyl group, the alkenyl group, the cycloalkenyl group, the alkynyl group, the cycloalkynyl group, and the aryl group represented by R^{S1} in formula (1S).

As the metal complex, the organometallic salt, the inorganic metal compound, and the organometallic compound, in addition to the foregoing, those described in Organic Transition Metal, Volumes 1 and 2 (written by John F. Hartwig, Tokyo Kagaku Dojin Co., Ltd., 2014), Shriver and Atkins' Inorganic Chemistry, Volumes 1 and 2 (written by M. Weller, T. Overton, J. Rourke, and F. Armstrong, Tokyo Kagaku Dojin Co., Ltd., 2016), and Dictionary of Inorganic Compounds & Complexes (written by Masayoshi Nakahara, Kodansha Scientific Ltd., 1997), etc. can also be used.

Hereinafter, specific examples of the metal compound will be given below, but the metal compound in the present invention is not limited thereto.

In the following specific examples, Ph represents a phenyl group, and Cy represents a cyclohexyl group.

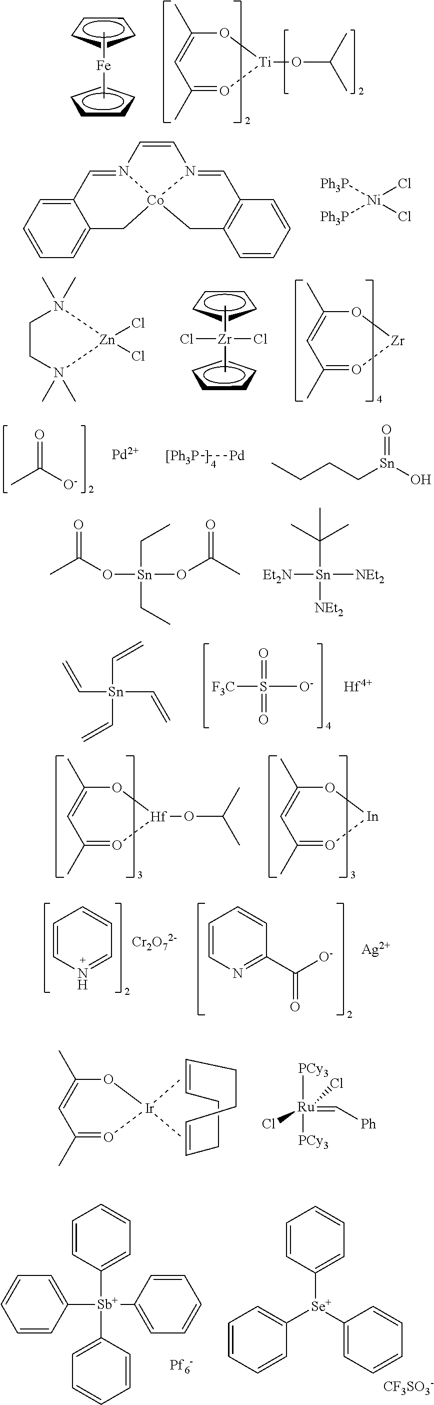

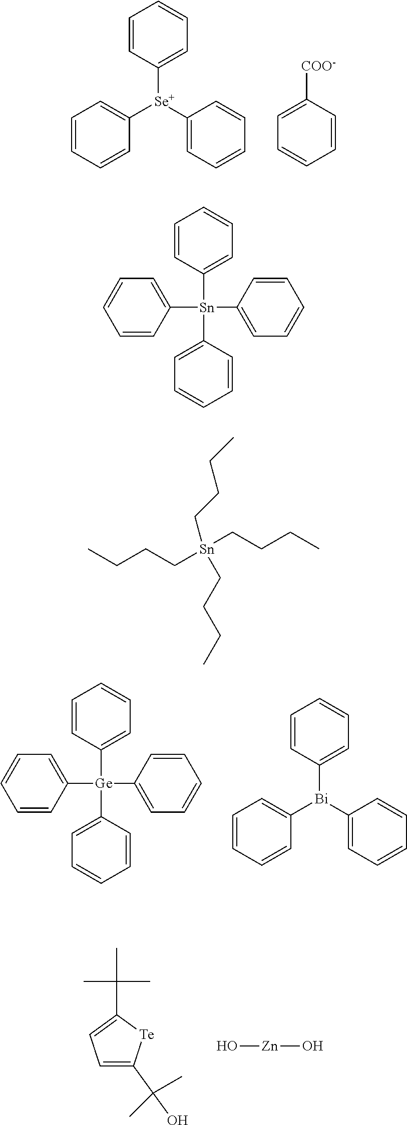

Examples of the metal-containing group include groups derived by removing any one or two hydrogen atoms from the metal compounds in the above specific examples and groups derived by removing any one substituent or ligand bonded to metal atoms of the metal compounds in the above specific examples. Specific examples are shown below. In the following specific examples, * represents a bonding position.

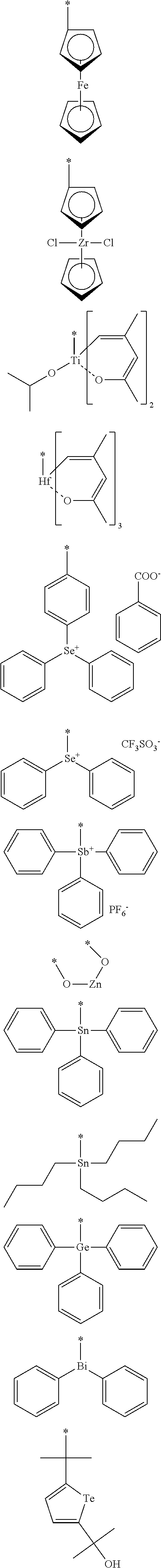

### Interactive Group

The resin (B) preferably has a group (hereinafter also referred to as an “interactive group”) that interacts with the above-described metal-containing group.

When the resin (B) has an interactive group, in unexposed portions, the resin (B) tends to aggregate due to the interaction between the interactive group and the metal-containing group. On the other hand, upon exposure, dissociation of the metal-containing group and the interactive group occurs, and as a result, the aggregated structure can be disaggregated. That is, due to this action, the dissolution contrast between unexposed portions and exposed portions of a resist film is further enhanced to provide good resolution, which is preferred.

The interactive group is, for example, at least one functional group selected from the group consisting of a hydroxyl group (an alcoholic hydroxyl group and a phenolic hydroxyl group), a carboxyl group, an amino group, an amide group, an imide group, a thiol group, an acetyl group, and an acetoxy group. In particular, the interactive group is preferably at least one functional group selected from the group consisting of a phenolic hydroxyl group and a carboxyl group.

The phenolic hydroxyl group means a hydroxyl group substituted on a ring-member atom of an aromatic ring (an aromatic hydrocarbon ring or an aromatic heterocyclic ring). One non-limiting example of the amide group is —C(═O)—NHR^{P} (R^{P} represents a hydrogen atom or an alkyl group having 1 to 5 carbon atoms).

The imide group is not particularly limited, but is preferably a group represented by formula (P) below.

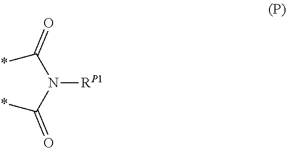

In formula (P), R^{P1} represents a hydrogen atom or a substituent. Each * represents the position of substitution. The substituent represented by R^{P1} is preferably an organic group, and examples of the organic group include groups given as examples of the organic group W described later.

### Repeating Unit Represented by Formula (1)

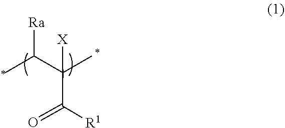

In formula (1), X represents a halogen atom, a fluorinated alkyl group, or a fluorinated cycloalkyl group.

Ra represents a hydrogen atom or a substituent.

R¹ represents a substituent. R¹ and Ra may be bonded to each other to form a ring.

When the repeating unit represented by formula (1) has a metal-containing group, it is preferred that Ra or R¹ in formula (1) be a group including the metal-containing group, and it is more preferred that R¹ be a group including the metal-containing group.

In formula (1), X represents a halogen atom, a fluorinated alkyl group, or a fluorinated cycloalkyl group.

Examples of the halogen atom represented by X include a fluorine atom, a chlorine atom, a bromine atom, and an iodine atom. In particular, for the advantageous effect of the present invention to be better produced, the halogen atom represented by X is preferably a chlorine atom, a bromine atom, or an iodine atom, more preferably a chlorine atom.

The fluorinated alkyl group represented by X is, for example, a group derived by substituting some or all hydrogen atoms of an alkyl group with fluorine atoms. The number of carbon atoms of the alkyl group is preferably 1 to 12, more preferably 1 to 6, still more preferably 1 to 3. The alkyl group may be linear or branched, and examples include linear or branched alkyl groups such as a methyl group, an ethyl group, a n-propyl group, an i-propyl group, a n-butyl group, a t-butyl group, and a n-hexyl group. For the advantageous effect of the present invention to be better produced, perfluoroalkyl groups are preferred.

The fluorinated cycloalkyl group represented by X is, for example, a group derived by substituting some or all hydrogen atoms of a cycloalkyl group with fluorine atoms. The number of carbon atoms of the cycloalkyl group is preferably 3 to 12, more preferably 3 to 6. For the advantageous effect of the present invention to be better produced, perfluorocycloalkyl groups are preferred.

For the advantageous effect of the present invention to be better produced, X is preferably a halogen atom, more preferably a chlorine atom.

In formula (1), Ra represents a hydrogen atom or a substituent.

The substituent represented by Ra may be an organic group or the above-described metal-containing group. Examples of the organic group include, but are not limited to, groups given as examples of the following organic group W.

### Organic Group W

The organic group W is, for example, an alkyl group, a cycloalkyl group, an alkenyl group, a cycloalkenyl group, an alkynyl group, a cycloalkynyl group, an aryl group, a heteroaryl group, an aralkyl group, a cyano group, an alkoxy group, an aryloxy group, a heterocyclic oxy group, an acyl group (an alkylcarbonyl group or an arylcarbonyl group), an acyloxy group (an alkylcarbonyloxy group or an arylcarbonyloxy group), a carbamoyloxy group, an alkoxycarbonyloxy group, an aryloxycarbonyloxy group, an alkylthio group, an arylthio group, a heterocyclic thio group, an alkylsulfinyl or arylsulfinyl group, an alkylsulfonyl or arylsulfonyl group, an aryloxycarbonyl group, an alkoxycarbonyl group, an aryl or heterocyclic azo group, a sulfonamide group, an imide group, an acylamino group, a carbamoyl group, or a lactone group.

Each of the groups given above may further have a substituent if possible. For example, an optionally substituted alkyl group is also included as a form of the organic group W. Examples of the substituent include, but are not limited to, one or more groups among the groups given as examples of the organic group W, halogen atoms, a nitro group, primary to tertiary amino groups, a phosphino group, a phosphinyl group, a phosphinyloxy group, a phosphinylamino group, a phosphono group, a silyl group, a hydroxy group, a carboxy group, a sulfonic group, and a phosphate group (hereinafter these are referred to as “substituents T”).

The number of carbon atoms of the organic group W is, for example, 1 to 20.

The number of atoms other than hydrogen atoms of the organic group W is, for example, 1 to 30.

The number of carbon atoms of the alkyl group given as an example of the organic group W is preferably 1 to 20, more preferably 1 to 10, still more preferably 1 to 6.

The alkyl group may be linear or branched.

Examples of the alkyl group include linear or branched alkyl groups such as a methyl group, an ethyl group, a n-propyl group, an i-propyl group, a n-butyl group, a t-butyl group, and a n-hexyl group.

In the optionally substituted alkyl group, examples of the optional substituent on the alkyl group include, but are not limited to, the groups listed as the substituents T above. From the viewpoint of improvement in resolution, the alkyl group also preferably has any of the interactive groups described above. To further improve the interactivity with an ionic compound (e.g., a photodecomposable onium salt compound) that can be included in the resist composition and is described in a later part and better produce the advantageous effect of the present invention, the alkyl group also preferably has, as the substituent, for example, a polar group such as a hydroxy group (e.g., an alcoholic hydroxyl group or a phenolic hydroxyl group), a carboxyl group, a sulfonic group, an amide group, or a sulfonamide group.

The alkyl moiety of the alkoxy group (including the alkoxy moiety in a substituent (e.g., an alkoxycarbonyloxy group) including an alkoxy group) given as an example of the organic group W, the alkyl moiety of the aralkyl group, the alkyl moiety of the alkylcarbonyl group, the alkyl moiety of the alkylcarbonyloxy group, the alkyl moiety of the alkylthio group, the alkyl moiety of the alkylsulfinyl group, and the alkyl moiety of the alkylsulfonyl group are each preferably the above alkyl group. In the optionally substituted alkoxy group, the optionally substituted aralkyl group, the optionally substituted alkylcarbonyloxy group, the optionally substituted alkylthio group, the optionally substituted alkylsulfinyl group, and the optionally substituted alkylsulfonyl group, examples of the optional substituents on the alkoxy group, the aralkyl group, the alkylcarbonyloxy group, the alkylthio group, the alkylsulfinyl group, and the alkylsulfonyl group are the same as those of the substituent on the optionally substituted alkyl group.

Examples of the cycloalkyl group given as an example of the organic group W include monocyclic cycloalkyl groups such as a cyclopentyl group and a cyclohexyl group and polycyclic cycloalkyl groups such as a norbornyl group, a tetracyclodecanyl group, a tetracyclododecanyl group, and an adamantyl group. The number of carbon atoms of the cycloalkyl group is preferably 5 to 20, more preferably 5 to 15. In the optionally substituted cycloalkyl group, examples of the optional substituent on the cycloalkyl group are the same as those of the substituent on the optionally substituted alkyl group.

The alkenyl group given as an example of the organic group W may be linear or branched. The number of carbon atoms of the alkenyl group is preferably 2 to 20. In the optionally substituted alkenyl group, examples of the optional substituent on the alkenyl group are the same as those of the substituent on the optionally substituted alkyl group.

The number of carbon atoms of the cycloalkenyl group given as an example of the organic group W is preferably 5 to 20. In the optionally substituted cycloalkenyl group, examples of the optional substituent on the cycloalkenyl group are the same as those of the substituent on the optionally substituted alkyl group.

The alkynyl group given as an example of the organic group W may be linear, branched, or cyclic. The number of carbon atoms of the alkynyl group is preferably 2 to 20. In the optionally substituted alkynyl group, examples of the optional substituent on the alkynyl group are the same as those of the substituent on the optionally substituted alkyl group.

The number of carbon atoms of the cycloalkynyl group given as examples of the organic group W is preferably 5 to 20. In the optionally substituted cycloalkynyl group, examples of the optional substituent on the cycloalkynyl group are the same as those of the substituent on the optionally substituted alkyl group.

The aryl group given as an example of the organic group W may be monocyclic or polycyclic (e.g., bicyclic to hexacyclic), unless otherwise specified.

The number of ring-member atoms of the aryl group is preferably 6 to 15, more preferably 6 to 10.

The aryl group is preferably a phenyl group, a naphthyl group, or an anthranil group, more preferably a phenyl group.

In the optionally substituted aryl group, examples of the optional substituent on the aryl group are the same as those of the substituent on the optionally substituted alkyl group.

Among the groups given as examples of the organic group W, examples of the aryl moiety in a substituent (e.g., an aryloxy group) including an aryl group are also the same as those of the aryl group given as an example of the organic group W.

The heteroaryl group given as an example of the organic group W may be monocyclic or polycyclic (e.g., bicyclic to hexacyclic), unless otherwise specified.

The number of heteroatoms that the heteroaryl group has as ring-member atoms is, for example, 1 to 10. Examples of the heteroatoms include a nitrogen atom, a sulfur atom, an oxygen atom, a selenium atom, a tellurium atom, a phosphorus atom, a silicon atom, and a boron atom.

The number of ring-member atoms of the heteroaryl group is preferably 5 to 15.

In the optionally substituted heteroaryl group, examples of the optional substituent on the heteroaryl group are the same as those of the substituent on the optionally substituted alkyl group.

The heterocyclic ring given as an example of the organic group W means a ring including a heteroatom as a ring-member atom. Unless otherwise specified, the heterocyclic ring may be an aromatic heterocycle or an aliphatic heterocycle and may be monocyclic or polycyclic (e.g., bicyclic to hexacyclic).

The number of heteroatoms that the heterocyclic ring has as ring-member atoms is, for example, 1 to 10. Examples of the heteroatoms include a nitrogen atom, a sulfur atom, an oxygen atom, a selenium atom, a tellurium atom, a phosphorus atom, a silicon atom, and a boron atom.

The number of ring-member atoms of the heterocyclic ring is preferably 5 to 15.

In the optionally substituted heterocyclic ring, examples of the optional substituent on the heterocyclic ring are the same as those of the substituent on the optionally substituted alkyl group.

The lactone group given as an example of the organic group W is preferably a five- to seven-membered lactone group, more preferably a five- to seven-membered lactone ring to which another ring structure is fused so as to form a bicyclo structure or a spiro structure.

In the optionally substituted lactone group, examples of the optional substituent on the lactone group are the same as those of the substituent on the optionally substituted alkyl group.

In particular, Ra is preferably a hydrogen atom.

In formula (1), R¹ represents a substituent.

The substituent represented by R¹ is preferably a group represented by formula (1a) below.

*-L^{1A}-R^{1A} (1a)

In formula (1a), L^{1A} represents a single bond, —O—, or —NR^{X}—. R^{X} represents a hydrogen atom or an organic group. R^{1A} represents a hydrogen atom or a substituent.

Examples of the organic group represented by R^{X} include, but are not limited to, groups given as examples of the organic group W.

In particular, R^{X} is preferably a hydrogen atom.

In formula (1a), R^{1A} represents a hydrogen atom or a substituent.

The substituent represented by R^{1A} may be an organic group or the above-described metal-containing group.

Examples of the organic group include, but are not limited to, groups given as examples of the organic group W.

In one embodiment, the organic group represented by R^{1A} may be a group represented by —C(R^{X1})(R^{X2})(R^{X3}). R^{X1} to R^{X3} each independently represent a linear or branched alkyl group or a cycloalkyl group.

The alkyl group and the cycloalkyl group represented by R^{X1} to R^{X3} are preferably, for example, the alkyl group and the cycloalkyl group given as examples of the organic group W.

Preferably, R^{X1} to R^{X3} each independently represent a linear or branched alkyl group (preferably, a linear alkyl group), or two of R^{X1} to R^{X3} are bonded to each other to form a monocyclic or polycyclic five- to eight-membered alicyclic ring.

The alkyl group or the cycloalkyl group represented by R^{X1} to R^{X3} may have a substituent. The substituent is not particularly limited, and example thereof are the same as those of the substituent on the optionally substituted alkyl group described above as the organic group W.

When the alkyl group represents a group represented by —C(R^{X1})(R^{X2})(R^{X3}), L^{1A} preferably represents —O— or —N(R^{X})—, more preferably represents-O—.

In one preferred embodiment, R^{1A} may represent a metal-containing group. In another preferred embodiment, R^{1A} may represent a hydrogen atom and form a carboxyl group or an amide group together with the carbonyl group and L^{1A} in formula (1).

R¹ and Ra may be bonded to each other to form a ring.

The ring formed by R¹ and Ra linked to each other is not particularly limited and may be monocyclic or polycyclic. The ring may include, as ring-member atoms, heteroatoms such as an oxygen atom, a nitrogen atom, and a sulfur atom and/or carbonyl carbon.

In particular, the ring is preferably a five- or six-membered alicyclic ring.

In particular, R¹ and Ra are preferably bonded to each other to form an imide group together with the carbonyl group in formula (1).

The repeating unit represented by formula (1) is preferably a repeating unit represented by formula (1-1) below.

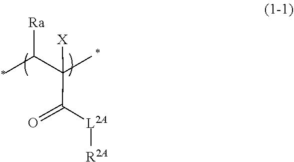

In formula (1-1), X represents a halogen atom, a fluorinated alkyl group, or a fluorinated cycloalkyl group.

Ra represents a hydrogen atom or a substituent.

L^{2A} represents —O— or —NR^{X}—. R^{X} represents a hydrogen atom or an organic group.

R^{2A} represents a hydrogen atom or a substituent.

Ra and R^{X} or R^{2A} may be bonded to each other to form a ring.

X and Ra in formula (1-1) respectively have the same definitions as X and Ra in formula (1), and preferred examples thereof are also the same.

R^{X} in —NR^{X}— represented by L^{2A} in formula (1-1) has the same definition as R^{X} in —NR^{X}— represented by L^{1A} in formula (1a), and preferred examples thereof are also the same.

R^{2A} in formula (1-1) has the same definition as R^{1A} in formula (1a), and preferred examples thereof are also the same.

Preferred examples of the ring formed by Ra and R^{X} or R^{2A} linked to each other include rings given as examples of the above-described ring formed by R¹ and Ra linked to each other.

Non-limiting specific examples of the repeating unit represented by formula (1) will be given below.

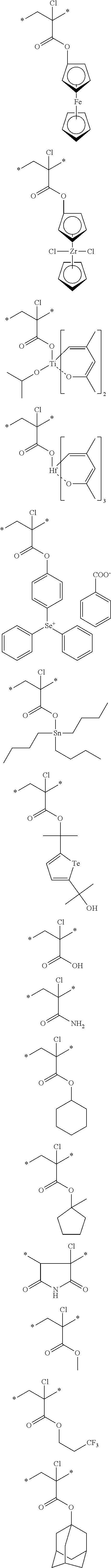

In the resin (B), the content of the repeating unit represented by formula (1) above is preferably 10 mol % or more, more preferably 20 mol % or more, still more preferably 40 mol % or more, relative to all the repeating units. The upper limit thereof is preferably 90 mol % or less, more preferably 80 mol % or less, still more preferably 70 mol % or less, particularly preferably 60 mol % or less, relative to all the repeating units.

The repeating unit represented by formula (1) included in the resin (B) may be of one single type or two or more types. When two or more types are included, it is preferred that the total content thereof be in the above preferred content range.

### Repeating Unit Represented by Formula (2)

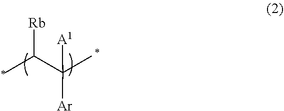

In formula (2), A¹ represents an optionally substituted alkyl or cycloalkyl group.

Rb represents a hydrogen atom or a substituent.

Ar represents an aromatic hydrocarbon group or a metal complex group. Ar and Rb may be bonded to each other to form a ring.

When the repeating unit represented by formula (2) has a metal-containing group, at least one of A¹, Rb, or Ar in formula (2) is a group including the metal-containing group, and Ar is preferably a group including the metal-containing group.

In formula (2), A¹ represents an optionally substituted alkyl or cycloalkyl group.

The alkyl group represented by A¹ may be a linear or branched alkyl group.

The linear or branched alkyl group represented by A¹ is preferably an alkyl group given as an example of the organic group W, more preferably an alkyl group having 1 to 6 carbon atoms, still more preferably a methyl group or an ethyl group, particularly preferably a methyl group.

The cycloalkyl group represented by A¹ is preferably a cycloalkyl group given as an example of the organic group W.

A¹ representing an alkyl group or a cycloalkyl group is a requirement for the progress of a main-chain decomposition reaction of the resin (B).

As described above, the alkyl group and the cycloalkyl group as A¹ may have a substituent.

In formula (2), Rb represents a hydrogen atom or a substituent.

The substituent represented by Rb may be an organic group or the above-described metal-containing group. Examples of the organic group include, but are not limited to, groups given as examples of the organic group W.

In particular, Rb is preferably a hydrogen atom.

In formula (2), Ar represents an aromatic hydrocarbon group or a metal complex group.

The aromatic hydrocarbon group represented by Ar is preferably, for example, an aryl group.

The aryl group is preferably an aryl group given as an example of the organic group W, more preferably a phenyl group.

The aryl group may have a substituent, and examples of the substituent include groups including the above-described metal-containing group, groups including the above-described interactive group, and in addition, the same examples as those of the substituent on the optionally substituted alkyl group described above as the organic group W. Alternatively, the aryl group may be a group having an onium salt structure.

The group including the metal-containing group is preferably a group represented by formula (1b) below.

*-L^{1B}-R^{1B} (1b)

In formula (1b), L^{1B} represents a single bond or a divalent linking group. R^{1B} represents the above-described metal-containing group.

Examples of the divalent linking group represented by L^{1B} include, but are not limited to, —CO—, —O—, —SO—, —SO₂—, —NR^{A}., alkylene groups (preferably having 1 to 6 carbon atoms, either linear or branched), cycloalkylene groups (preferably having 3 to 15 carbon atoms), arylene groups (preferably six- to ten-membered rings, more preferably six-membered rings), and divalent linking groups formed by combining two or more of them. R^{A} may be a hydrogen atom or an alkyl group having 1 to 6 carbon atoms.

L^{1B} is preferably a single bond, —O—, —COO—, or —CONR^{A}—.

The group including the interactive group is preferably a group represented by formula (2b) below.

*-L^{2B}-R^{2B} (2b)

In formula (2b), L^{2B} represents a single bond or a divalent linking group. R^{2B} represents the above-described interactive group.

Examples of the divalent linking group represented by L^{2B} include the linking groups given as examples of the divalent linking group represented by L^{1B} in formula (1b).

L^{2B} is preferably a single bond or an alkylene group.

The group including an onium salt structure is preferably a group represented by formula (O1) below.

*-L_{T}-X_{A}⁻M_{A}⁺ Formula (O1)

In formula (O1), L_{T} represents a single bond or a divalent linking group. Examples of the divalent linking group represented by L_{T} include the above-described linking groups given as examples of the divalent linking group represented by L^{1B} in formula (1b). X_{A}⁻ represents a monovalent organic anionic group. M_{A}⁺ represents an organic cation.

The monovalent organic anionic group represented by X_{A}⁻ is preferably a non-nucleophilic anionic group (an anionic group with a very low ability to cause a nucleophilic reaction).

In formula (O1), the monovalent anionic group represented by X_{A}⁻ is not particularly limited, but is preferably, for example, a group selected from the group consisting of groups represented by formulas (B-1) to (B-14), which will be described later in the section of Ionic Compound (C).

The organic cation represented by M_{A}⁺ in formula (O1) is preferably an organic cation represented by formula (ZaI) (cation (ZaI)) or an organic cation represented by formula (ZaII) (cation (ZaII)), which will be described later in the section of Ionic Compound (C).

Examples of the metal complex group represented by Ar include groups derived by removing any one hydrogen atom or any one ligand from the metal complexes exemplified in the description of the metal-containing group above.

Ar and Rb may be bonded to each other to form a ring.

The ring formed by Ar and Rb linked to each other is not particularly limited and may be monocyclic or polycyclic. The ring may include, as ring-member atoms, heteroatoms such as an oxygen atom, a nitrogen atom, and a sulfur atom and/or carbonyl carbon.

In particular, the ring is preferably a five- or six-membered alicyclic ring.

In one preferred embodiment, the repeating unit represented by formula (2) may be a repeating unit represented by any one of formulas (2-1) to (2-3) below. The repeating units represented by formulas (2-1) and (2-3) each correspond to a repeating unit including the above-described metal-containing group, and formula (2-2) corresponds to a repeating unit including the above-described interactive group.

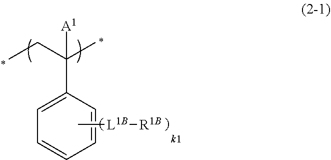

In formula (2-1), A¹ represents an optionally substituted alkyl or cycloalkyl group. L^{1B} represents a single bond or a divalent linking group. R^{1B} represents the above-described metal-containing group. k1 represents an integer of 1 to 5. When k1 is an integer of 2 or greater, a plurality of L^{1B}'s may be the same as or different from each other, and a plurality of R^{1B}'s may be the same as or different from each other.

A¹ in formula (2-1) has the same definition as A¹ in formula (2) above, and preferred examples thereof are also the same.

L^{1B} and R^{1B} in formula (2-1) have the same definitions as L^{1B} and R^{1B} in formula (1b) above, and preferred examples thereof are also the same.

k1 is preferably 1 or 2, more preferably 1.

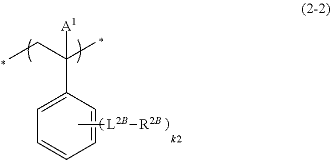

In formula (2-2), A¹ represents an optionally substituted alkyl or cycloalkyl group. L^{2B} represents a single bond or a divalent linking group. R^{2B} represents the above-described interactive group. k2 represents an integer of 1 to 5. When k2 is an integer of 2 or greater, a plurality of L^{2B}'s may be the same as or different from each other, and a plurality of R^{2B}'s may be the same as or different from each other.

A¹ in formula (2-2) has the same definition as A¹ in formula (2) above, and preferred examples thereof are also the same.

L^{2B} and R^{2B} in formula (2-2) have the same definitions as L^{2B} and R^{2B} in formula (2b) above, and preferred examples thereof are also the same.

k2 is preferably 1 or 2.

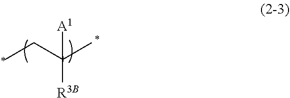

In formula (2-3), A¹ represents an optionally substituted alkyl or cycloalkyl group. R^{3B} represents a metal complex group.

A¹ in formula (2-3) has the same definition as A¹ in formula (2) above, and preferred examples thereof are also the same. The metal complex group represented by R^{3B} in formula (2-3) is the same as the metal complex group represented by Ar in formula (2) above, and preferred examples thereof are also the same.

Non-limiting specific examples of the repeating unit represented by formula (2) will be given below.

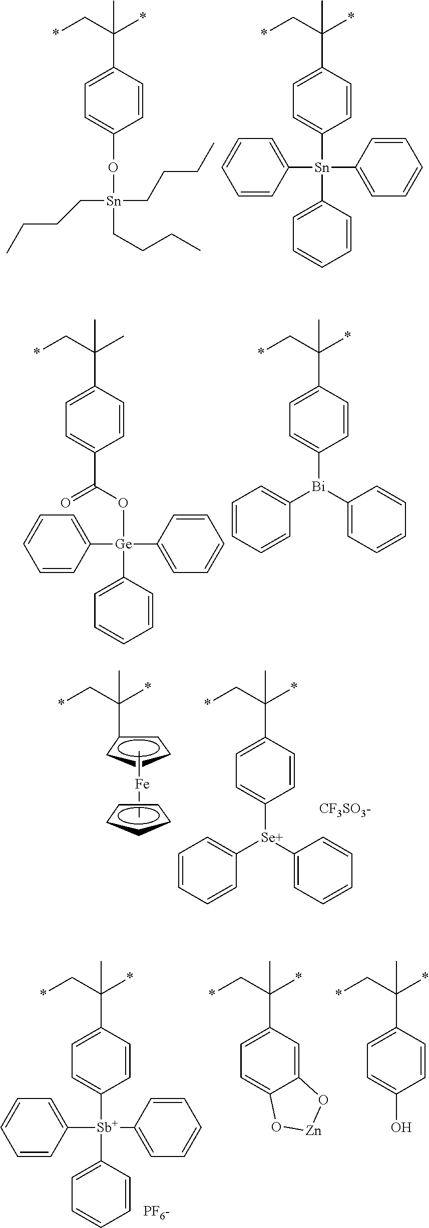

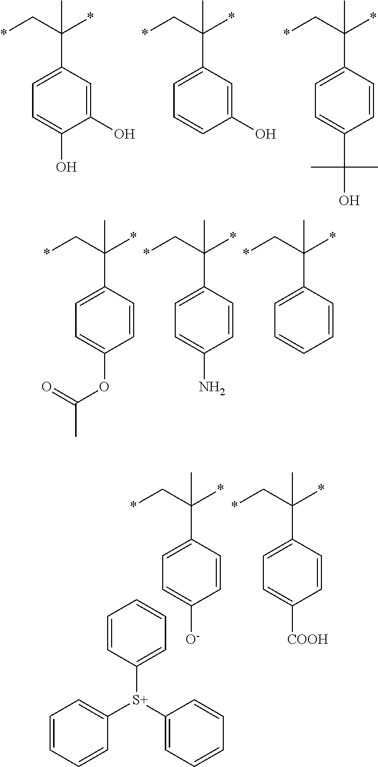

In the resin (B), the content of the repeating unit represented by formula (2) above is preferably 10 mol % or more, more preferably 20 mol % or more, still more preferably 40 mol % or more, relative to all the repeating units. The upper limit thereof is, for example, preferably 95 mol % or less, more preferably 90 mol % or less, still more preferably 80 mol % or less, particularly preferably 60 mol % or less, relative to all the repeating units.

The repeating unit represented by formula (2) included in the resin (B) may be of one single type or two or more types. When two or more types are included, it is preferred that the total content thereof be in the above preferred content range.

In the resin (B), the total content of the repeating unit represented by formula (1) above and the repeating unit represented by formula (2) above is preferably 90 mol % or more, more preferably 95 mol % or more, relative to all the repeating units. The upper limit is preferably 100 mol % or less.

In the resin (B), the content of a repeating unit that is the repeating unit represented by formula (1) above or the repeating unit represented by formula (2) above and that has the above-described metal-containing group is preferably 1 mol % or more, more preferably 10 mol % or more, relative to all the repeating units. The upper limit is preferably 100 mol % or less, more preferably 90 mol % or less.

When the resin (B) is a copolymer including the repeating unit represented by formula (1) above and the repeating unit represented by formula (2) above, the copolymer may be in any form, such as a random copolymer, a block copolymer, or an alternating copolymer (a copolymer in which the repeating unit represented by formula (1) above and the repeating unit represented by formula (2) above are alternately arranged, for example, as ABAB . . . ), and is particularly preferably an alternating copolymer.

In one preferred embodiment of the resin (B), the proportion of the alternating copolymer in the resin (B) may be 90 mass % or more (preferably 100 mass % or more) relative to the total mass of the resin (B).

### Other Repeating Units

The resin (B) may include other repeating units other than the repeating units described above to the extent that the advantageous effect of the present invention is not impaired.

The weight-average molecular weight of the resin (B) is preferably 5,000 or more, more preferably 10,000 or more, still more preferably 20,000 or more.

The weight-average molecular weight of the resin (B) is preferably 200,000 or less, more preferably 150,000 or less, still more preferably 100,000 or less, particularly preferably 85,000 or less.

The value of the weight-average molecular weight is a value determined by GPC in terms of polystyrene.

The dispersity (molecular weight distribution) of the resin (B) is typically 1.0 to 5.0, preferably 1.0 to 3.0, more preferably 1.2 to 3.0, still more preferably 1.2 to 2.5. A dispersity in the above range tends to lead to a higher resolution and a better resist profile.

The resin (B) can be synthesized according to a conventional method (e.g., radical polymerization).

In the resist composition according to the present invention, the content of the resin (B) is preferably 50.0 mass % or more, more preferably 60.0 mass % or more, still more preferably 70.0 mass % or more, relative to the total solid contents of the composition. The upper limit is 100 mass % or less, preferably 99.9 mass % or less.

The resin (B) used may be of one type or a combination of two or more types. When two or more types are used, it is preferred that the total content thereof be in the above preferred content range.

The resist composition according to the present invention may include other components other than the resin (B).

Examples of the other components include, but are not limited to, metal compounds, ionic compounds (specifically, photodecomposable onium salt compounds), surfactants, and solvents.

### Metal Compound (A)

The resist composition according to the present invention preferably includes at least one metal compound (hereinafter also referred to as a metal compound (A)) selected from the group consisting of a metal complex, an organometallic salt, and an organometallic compound.

It is considered that when the resist composition includes a metal compound (A), secondary electrons are generated also from the metal compound upon irradiation with an actinic ray or a radiation, so that the amount of secondary electrons generated in a resist film increases, and the main-chain decomposition of the resin (B) is further promoted, thus resulting in further improved sensitivity. In addition, the presence of a metal provides good etching resistance.

When the resist composition includes a metal compound (A), the resin (B) included in the resist composition preferably has the above-described interactive group.

When the resin (B) has the interactive group, in unexposed portions, the resin (B) tends to aggregate due to the interaction between the interactive group and the metal compound (A). On the other hand, upon exposure, dissociation of the metal compound (A) and the interactive group occurs, and as a result, the aggregated structure can be disaggregated. That is, due to this action, the dissolution contrast between unexposed portions and exposed portions of a resist film is further enhanced to provide better resolution, which is preferred.

Examples of the metal atom included in the metal compound include the metal atoms exemplified in the description of the metal-containing group above, and preferred examples thereof are also the same.

Examples of the metal complex, the organometallic salt, and the organometallic compound include the metal complexes, the organometallic salts, and the organometallic compounds exemplified in the description of the metal-containing group above, and preferred examples thereof are also the same.

When the resist composition according to the present invention includes a metal compound (A), the content of the metal compound (A) is preferably 0.1 mass % or more, more preferably 1 mass % or more, still more preferably 3 mass % or more, relative to the total solid contents of the resist composition. The upper limit is preferably 50 mass % or less, more preferably 40 mass % or less, still more preferably 35 mass % or less.

The metal compound (A) used may be of one type or a combination of two or more types. When two or more types are used, it is preferred that the total content thereof be in the above preferred content range.

In the resist composition according to the present invention, the content of the metal compound (A) is preferably 1 to 40 mass %, more preferably 1 to 35 mass %, still more preferably 1 to 30 mass %, relative to the content of the resin (B).

### Ionic Compound (C)

The resist composition according to the present invention preferably includes an ionic compound.

The ionic compound (C) may be a compound that decomposes upon irradiation with an actinic ray or a radiation or a compound that does not decompose. The compound that decomposes upon irradiation with an actinic ray or a radiation may be a compound that decomposes upon irradiation with an actinic ray or a radiation to generate an acid or a compound that decomposes upon irradiation with an actinic ray or a radiation to generate a base.

The ionic compound is more preferably a compound having an onium salt structure (a photodecomposable onium salt compound) that generates an acid upon irradiation with an actinic ray or a radiation.

When the resist composition includes an ionic compound such as a photodecomposable onium salt compound, in unexposed portions, the resin (B) tends to aggregate with the ionic compound via a polar group that can be included in the resin (B). On the other hand, upon exposure, dissociation of the ionic compound and the polar group and cleavage of the photodecomposable onium salt compound occur, and as a result, the aggregated structure can be disaggregated. That is, due to this action, the dissolution contrast between unexposed portions and exposed portions of a resist film tends to be further enhanced, leading to higher resolution.

When the resist composition includes an ionic compound such as a photodecomposable onium salt compound, the resin (B) included in the resist composition preferably has a polar group. Examples of the polar group include a hydroxy group (e.g., an alcoholic hydroxyl group and a phenolic hydroxyl group), a carboxyl group, a sulfonic group, an amide group, and a sulfonamide group. The polar group may be a group described above as the interactive group.

Hereinafter, the photodecomposable onium salt compound will be described.

The photodecomposable onium salt compound is preferably a compound that has at least one salt structure moiety composed of an anionic moiety and a cationic moiety and that decomposes upon exposure to generate an acid (preferably an organic acid).

To readily decompose upon exposure and produce an organic acid with higher productivity, the salt structure moiety of the photodecomposable onium salt compound is particularly preferably composed of an organic cationic moiety and an organic anionic moiety with very low nucleophilicity.

The salt structure moiety may constitute a part or the whole of the photodecomposable onium salt compound. For example, a structure in which two or more salt structure moieties are linked to each other, such as a photodecomposable onium salt PG2 described later, corresponds to the case where the salt structure moiety constitutes a part of the photodecomposable onium salt compound.

The number of salt structure moieties in the photodecomposable onium salt is not particularly limited, but is preferably 1 to 10, preferably 1 to 6, still more preferably 1 to 3.

Examples of the above-described organic acid that is generated from the photodecomposable onium salt compound by the action of exposure include sulfonic acids (e.g., aliphatic sulfonic acids, aromatic sulfonic acids, and camphorsulfonic acid), carboxylic acids (e.g., aliphatic carboxylic acids, aromatic carboxylic acids, and aralkyl carboxylic acids), carbonylsulfonylimidic acid, bis(alkylsulfonyl)imidic acids, and tris(alkylsulfonyl)methide acids.

The organic acid that is generated from the photodecomposable onium salt compound by the action of exposure may be a polyacid having two or more acidic groups. For example, when the photodecomposable onium salt compound is a photodecomposable onium salt compound PG2 described later, the organic acid resulting from the decomposition of the photodecomposable onium salt compound upon exposure is a polyacid having two or more acidic groups.

In the photodecomposable onium salt compound, the cationic moiety constituting the salt structure moiety is preferably an organic cationic moiety, particularly preferably an organic cation represented by formula (ZaI) (cation (ZaI)) or an organic cation represented by formula (ZaII) (cation (ZaII)) described later.

### Photodecomposable Onium Salt Compound PG1

One preferred example of the photodecomposable onium salt compound is an onium salt compound that is expressed as “M⁺ X⁻” and that generates an organic acid upon exposure (hereinafter also referred to as a “photodecomposable onium salt compound PG1”).

In the compound expressed as “M⁺ X⁻”, M⁺ represents an organic cation, and X⁻ represents an organic anion.

Hereinafter, the photodecomposable onium salt compound PG1 will be described.

The organic cation represented by M⁺ in the photodecomposable onium salt compound PG1 is preferably an organic cation represented by formula (ZaI) (cation (ZaI)) or an organic cation represented by formula (ZaII) (cation (ZaII)).

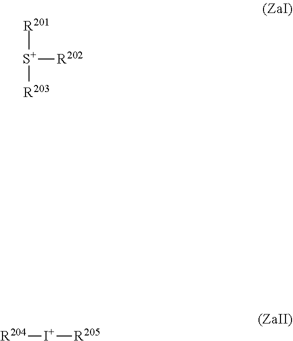

In formula (ZaI) above, R²⁰¹, R²⁰², and R²⁰³ each independently represent an organic group.

The number of carbon atoms of each of the organic groups represented by R²⁰¹, R²⁰², and R²⁰³ is typically 1 to 30, preferably 1 to 20. Two of R²⁰¹ to R²⁰³ may be bonded to each other to form a ring structure, and the ring may include an oxygen atom, a sulfur atom, an ester group, an amide group, or a carbonyl group. Examples of the group formed by two of R²⁰¹ to R²⁰³ bonded to each other include alkylene groups (e.g., a butylene group and a pentylene group) and —CH₂—CH₂—O—CH₂—CH₂—.

Examples of preferred embodiments of the organic cation represented by formula (ZaI) include a cation (ZaI-1), a cation (ZaI-2), an organic cation represented by formula (ZaI-3b) (cation (ZaI-3b)), and an organic cation represented by formula (ZaI-4b) (cation (ZaI-4b)) described below.

First, the cation (ZaI-1) will be described.

The cation (ZaI-1) is an arylsulfonium cation represented by formula (ZaI) above where at least one of R²⁰¹ to R²⁰³ is an aryl group.

In the arylsulfonium cation, all of R²⁰¹ to R²⁰³ may be aryl groups, or some of R²⁰¹ to R²⁰³ may be aryl groups with the other being an alkyl group or a cycloalkyl group.

Alternatively, one of R²⁰¹ to R²⁰³ may be an aryl group with the other two of R²⁰¹ to R²⁰³ being bonded to each other to form a ring structure, and the ring may include an oxygen atom, a sulfur atom, an ester group, an amide group, or a carbonyl group. Examples of the group formed by two of R²⁰¹ to R²⁰³ bonded to each other include alkylene groups (e.g., a butylene group, a pentylene group, and —CH₂—CH₂—O—CH₂—CH₂—) in which one or more methylene groups are optionally substituted with an oxygen atom, a sulfur atom, an ester group, an amide group, and/or a carbonyl group.

Examples of the arylsulfonium cation include triarylsulfonium cations, diarylalkylsulfonium cations, aryldialkylsulfonium cations, diarylcycloalkylsulfonium cations, and aryldicycloalkylsulfonium cations.

The aryl group included in the arylsulfonium cation is preferably a phenyl group or a naphthyl group, more preferably a phenyl group. The aryl group may be an aryl group having a heterocyclic ring structure having an oxygen atom, a nitrogen atom, a sulfur atom, or the like. Examples of the heterocyclic ring structure include a pyrrole residue, a furan residue, a thiophene residue, an indole residue, a benzofuran residue, and a benzothiophene residue. When the arylsulfonium cation has two or more aryl groups, the two or more aryl groups may be the same or different.

The alkyl group or the cycloalkyl group that the arylsulfonium cation optionally has is preferably a linear alkyl group having 1 to 15 carbon atoms, a branched alkyl group having 3 to 15 carbon atoms, or a cycloalkyl group having 3 to 15 carbon atoms, more preferably, for example, a methyl group, an ethyl group, a propyl group, a n-butyl group, a sec-butyl group, a t-butyl group, a cyclopropyl group, a cyclobutyl group, or a cyclohexyl group.

The optional substituents on the aryl group, the alkyl group, and the cycloalkyl group represented by R²⁰¹ to R²⁰³ are each independently preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (e.g., fluorine or iodine), a hydroxyl group, a carboxyl group, an ester group, a sulfinyl group, a sulfonyl group, an alkylthio group, a phenylthio group, or the like.

These substituents may further have a substituent if possible; for example, the alkyl group also preferably has a halogen atom as a substituent to be a halogenated alkyl group such as a trifluoromethyl group.

Next, the cation (ZaI-2) will be described.

The cation (ZaI-2) is a cation represented by formula (ZaI) where R²⁰¹ to R²⁰³ each independently represent an organic group having no aromatic rings. Here, the aromatic rings also encompass aromatic rings including a heteroatom.

The organic group having no aromatic rings represented by R²⁰¹ to R²⁰³ has generally 1 to 30 carbon atoms, preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, still more preferably a linear or branched 2-oxoalkyl group.

Examples of the alkyl group and the cycloalkyl group represented by R²⁰¹ to R²⁰³ include linear alkyl groups having 1 to 10 carbon atoms and branched alkyl groups having 3 to 10 carbon atoms (e.g., a methyl group, an ethyl group, a propyl group, a butyl group, and a pentyl group), and cycloalkyl groups having 3 to 10 carbon atoms (e.g., a cyclopentyl group, a cyclohexyl group, and a norbornyl group).

R²⁰¹ to R²⁰³ may be further substituted with a halogen atom, an alkoxy group (having, for example, 1 to 5 carbon atoms), a hydroxyl group, a cyano group, or a nitro group.

Next, the cation (ZaI-3b) will be described.

The cation (ZaI-3b) is a cation represented by formula (ZaI-3b) below.

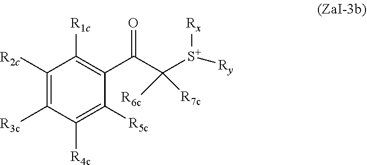

In formula (ZaI-3b), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group (e.g., a t-butyl group), a cycloalkyl group, a halogen atom, a cyano group, or an aryl group.

R_{X} and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and R_{X}, and R_{X} and R_{y} may independently be bonded to each other to form rings, and these rings may each independently include an oxygen atom, a sulfur atom, a ketone group, an ester bond, or an amide bond.

Examples of such a ring include aromatic or non-aromatic hydrocarbon rings, aromatic or non-aromatic heterocyclic rings, and polycyclic fused rings formed by combining two or more of these rings. The ring is, for example, a three- to ten-membered ring, preferably a four- to eight-membered ring, more preferably a five- or six-membered ring.

Examples of the groups formed by any two or more of R_{1c} to R_{5c}, R_{6c} and R_{7c}, and R_{X} and R_{y} bonded to each other include alkylene groups such as a butylene group and a pentylene group. In these alkylene groups, a methylene group may be substituted with a heteroatom such as an oxygen atom.

The groups formed by R_{5c} and R_{6c} and R_{5c} and R_{X} bonded to each other are preferably single bonds or alkylene groups. Examples of the alkylene groups include a methylene group and an ethylene group.

R_{1c} to R_{5c}, R_{6c}, R_{7c}, R_{X}, R_{y}, and the rings formed by any two or more of R_{1c} to R_{5c}, R_{5c} and R_{6c}, R_{6c} and R_{7c}, R_{5c} and R_{X}, and R_{X} and R_{y} individually bonded to each other may have a substituent.

Next, the cation (ZaI-4b) will be described.

The cation (ZaI-4b) is a cation represented by formula (ZaI-4b) below.

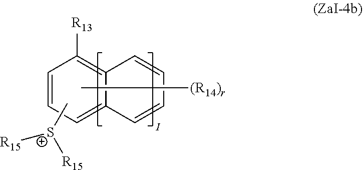

In formula (ZaI-4b), 1 represents an integer of 0 to 2.

r represents an integer of 0 to 8.

R₁₃ represents a hydrogen atom, a halogen atom (e.g., a fluorine atom or an iodine atom), a hydroxyl group, an alkyl group, a halogenated alkyl group, an alkoxy group, a carboxyl group, an alkoxycarbonyl group, or a group having a cycloalkyl group (either a cycloalkyl group as such or a group including a cycloalkyl group as a part). These groups may have a substituent.

R₁₄ represents a hydroxyl group, a halogen atom (e.g., a fluorine atom or an iodine atom), an alkyl group, a halogenated alkyl group, an alkoxy group, an alkoxycarbonyl group, an alkylcarbonyl group, an alkylsulfonyl group, a cycloalkylsulfonyl group, or a group having a cycloalkyl group (either a cycloalkyl group as such or a group including a cycloalkyl group as a part). These groups may have a substituent. When a plurality of R₁₄'s are present, they each independently represent any of these groups such as a hydroxyl group.

R₁₅'s each independently represent an alkyl group, a cycloalkyl group, or a naphthyl group. Two R₁₅'s may be bonded to each other to form a ring. When two R₁₅'s are bonded to each other to form a ring, the ring may include, in its skeleton, a heteroatom such as an oxygen atom or a nitrogen atom. In one embodiment, two R₁₅'s are preferably alkylene groups and bonded to each other to form a ring structure. The alkyl group, the cycloalkyl group, the naphthyl group, and the ring formed by two R₁₅'s bonded to each other may have a substituent.

In formula (ZaI-4b), the alkyl groups represented by R₁₃, R₁₄, and R₁₅ are preferably linear or branched. The number of carbon atoms of each of the alkyl groups is preferably 1 to 10. The alkyl groups are more preferably each a methyl group, an ethyl group, a n-butyl group, a t-butyl group, or the like.

Next, formula (ZaII) will be described.

In formula (ZaII), R²⁰⁴ and R²⁰⁵ each independently represent an aryl group, an alkyl group, or a cycloalkyl group.

The aryl group represented by R²⁰⁴ and R²⁰⁵ is preferably a phenyl group or a naphthyl group, more preferably a phenyl group. The aryl group represented by R²⁰⁴ and R²⁰⁵ may be an aryl group having a heterocyclic ring having an oxygen atom, a nitrogen atom, a sulfur atom, or the like. Examples of the skeleton of the aryl group having a heterocyclic ring include pyrrole, furan, thiophene, indole, benzofuran, and benzothiophene.

The alkyl group represented by R²⁰⁴ and R²⁰⁵ is preferably a linear alkyl group having 1 to 10 carbon atoms or a branched alkyl group having 3 to 10 carbon atoms (e.g., a methyl group, an ethyl group, a propyl group, a butyl group, or a pentyl group), and the cycloalkyl group represented by R²⁰⁴ and R²⁰⁵ is preferably a cycloalkyl group having 3 to 10 carbon atoms (e.g., a cyclopentyl group, a cyclohexyl group, or a norbornyl group).

The aryl group, the alkyl group, and the cycloalkyl group represented by R²⁰⁴ and R²⁰⁵ may each independently have a substituent. Examples of the optional substituents on the aryl group, the alkyl group, and the cycloalkyl group represented by R²⁰⁴ and R²⁰⁵ include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxyl group, and a phenylthio group.

Specific examples of the organic cation represented by M⁺ are shown below, but the present invention is not limited thereto.

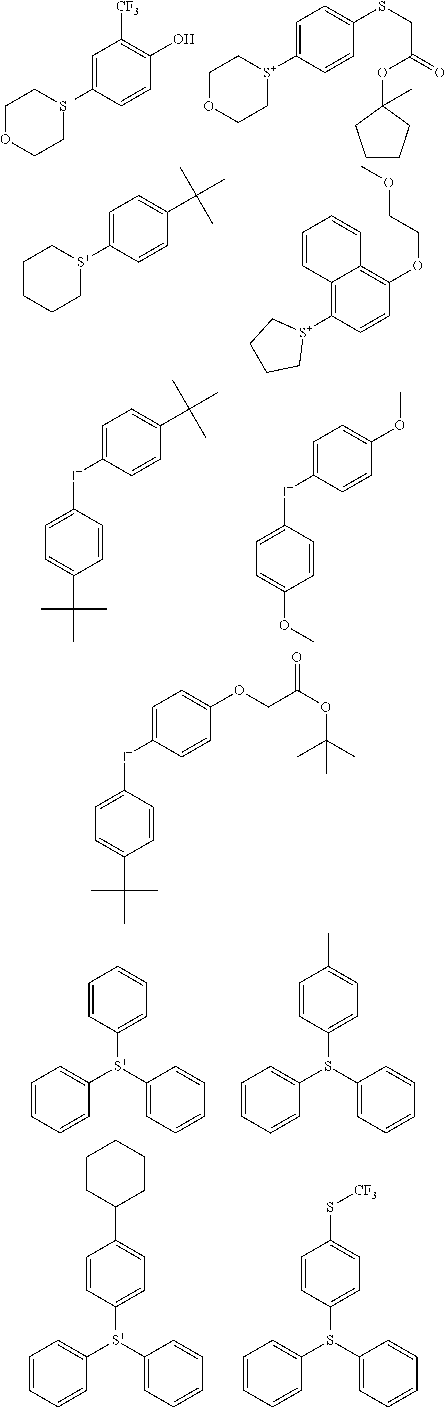

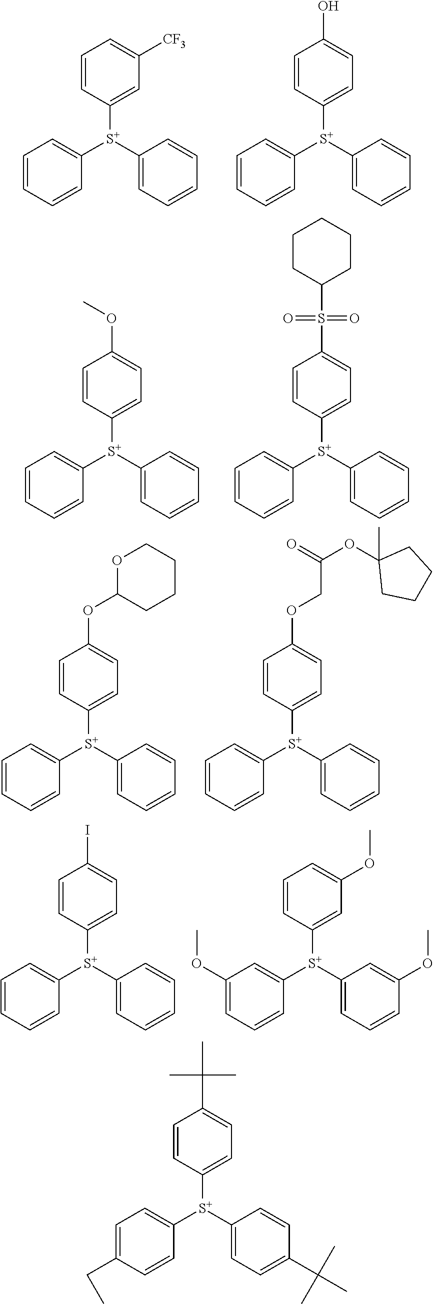

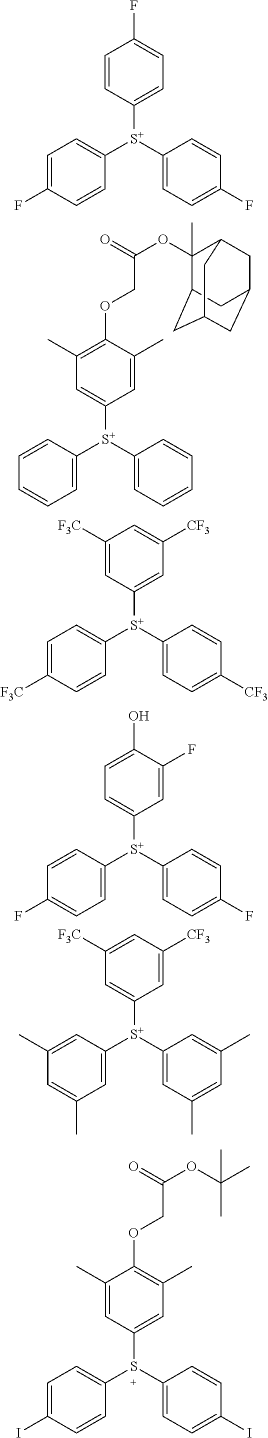

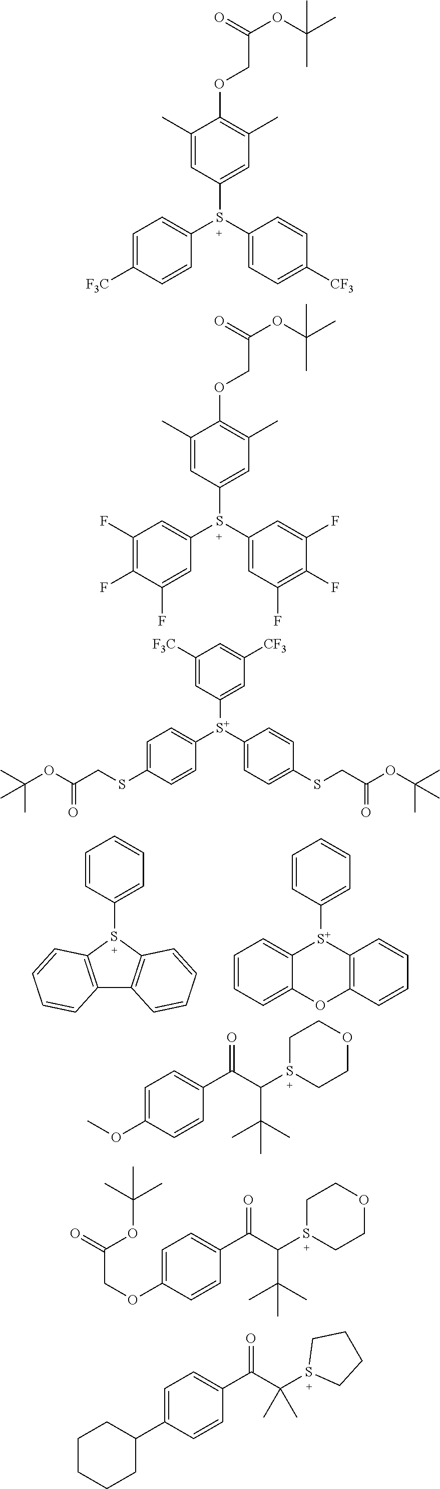

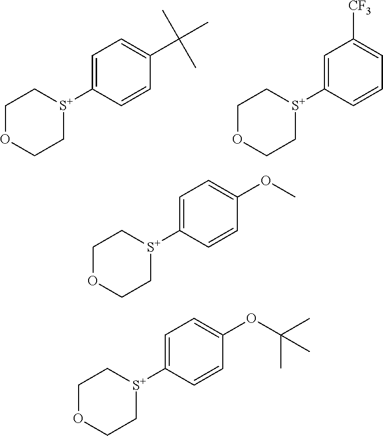 [SMILES: CC(C)(C)c1ccc([S+]2CCOCC2)cc1 ; FC(F)(F)c1cccc([S+]2CCOCC2)c1 ; COc1ccc([S+]2CCOCC2)cc1 ; CC(C)(C)Oc1ccc([S+]2CCOCC2)cc1]

The organic anion represented by X⁻ in the photodecomposable onium salt compound PG1 is preferably a non-nucleophilic anion (an anion with a very low ability to cause a nucleophilic reaction).

Examples of the non-nucleophilic anion include sulfonate anions (e.g., aliphatic sulfonate anions, aromatic sulfonate anions, and a camphorsulfonate anion), carboxylate anions (e.g., aliphatic carboxylate anions, aromatic carboxylate anions, and aralkyl carboxylate anions), a sulfonylimide anion, bis(alkylsulfonyl)imide anions, and tris(alkylsulfonyl)methide anions.

The organic anion is also preferably, for example, an organic anion represented by formula (DA) below.

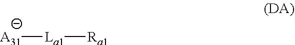

In formula (DA), A₃₁⁻ represents an anionic group. Rₐ₁ represents a hydrogen atom or a monovalent organic group. Lₐ₁ represents a single bond or a divalent linking group.

A₃₁⁻ represents an anionic group. The anionic group represented by A₃₁⁻ is not particularly limited, but is preferably, for example, a group selected from the group consisting of groups represented by formulas (B-1) to (B-14), more preferably a group represented by formula (B-1), formula (B-2), formula (B-3), formula (B-4), formula (B-5), formula (B-6), formula (B-10), formula (B-12), formula (B-13), or formula (B-14).

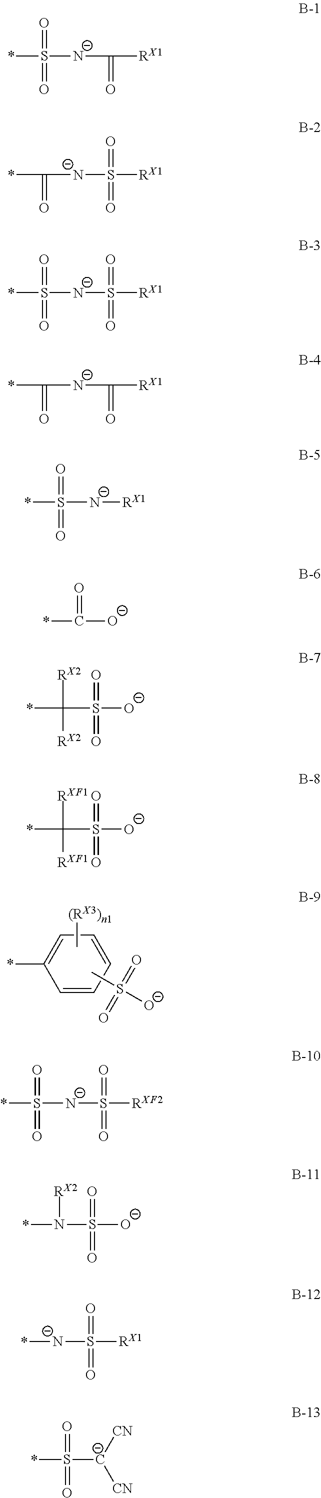

*—O⁻ Formula (B-14)

In formulas (B-1) to (B-14), * represents a bonding position.

In formulas (B-1) to (B-5) and formula (B-12), each R^{X1} independently represents a monovalent organic group.

In formula (B-7) and formula (B-11), each R^{X2} independently represents a hydrogen atom or a substituent other than a fluorine atom and perfluoroalkyl groups. Two R^{X2}'s in formula (B-7) may be the same or different.

In formula (B-8), R^{XF1} represents a hydrogen atom, a fluorine atom, or a perfluoroalkyl group, provided that at least one of two R^{XF1}'s represents a fluorine atom or a perfluoroalkyl group. Two R^{XF1}'s in formula (B-8) may be the same or different.

In formula (B-9), R^{X3} represents a hydrogen atom, a halogen atom, or a monovalent organic group. n1 represents an integer of 0 to 4. When n1 represents an integer of 2 to 4, a plurality of R^{X3}'s may be the same or different.

In formula (B-10), R^{XF2} represents a fluorine atom or a perfluoroalkyl group.

The partner bonded to the bonding position represented by * in formula (B-14) is preferably an optionally substituted phenylene group. The optional substituent on the phenylene group is, for example, a halogen atom.

In formulas (B-1) to (B-5) and formula (B-12), each R^{X1} independently represents a monovalent organic group.

R^{X1} is preferably an alkyl group (which may be linear or branched and preferably has 1 to 15 carbon atoms), a cycloalkyl group (which may be monocyclic or polycyclic and preferably has 3 to 20 carbon atoms), or an aryl group (which may be monocyclic or polycyclic and preferably has 6 to 20 carbon atoms). The group represented by R^{X1} may have a substituent.

In R^{X1} in formula (B-5), the atom directly bonded to N— is also preferably neither the carbon atom in-CO-nor the sulfur atom in —SO₂—.

The cycloalkyl group represented by R^{X1} may be monocyclic or polycyclic.

Examples of the cycloalkyl group represented by R^{X1} include a norbornyl group and an adamantyl group.

The optional substituent on the cycloalkyl group represented by R^{X1} is not particularly limited, but is preferably an alkyl group (which may be linear or branched and preferably has 1 to 5 carbon atoms). One or more carbon atoms that are ring-member atoms of the cycloalkyl group represented by R^{X1} may be replaced with carbonyl carbon atoms.

The number of carbon atoms of the alkyl group represented by R^{X1} is preferably 1 to 10, more preferably 1 to 5.

The optional substituent on the alkyl group represented by R^{X1} is not particularly limited, but is preferably, for example, a cycloalkyl group, a fluorine atom, or a cyano group.

Examples of the cycloalkyl group serving as the substituent are the same as the cycloalkyl groups described in the case where R^{X1} is a cycloalkyl group.

When the alkyl group represented by R^{X1} has a fluorine atom serving as the substituent, the alkyl group may be a perfluoroalkyl group.

In the alkyl group represented by R^{X1}, one or more —CH₂— moieties may be substituted with carbonyl groups.

The aryl group represented by R^{X1} is preferably a benzene ring group.

The optional substituent on the aryl group represented by R^{X1} is not particularly limited, but is preferably an alkyl group, a fluorine atom, or a cyano group. Examples of the alkyl group serving as the substituent are the same as the alkyl groups described in the case where R^{X1} is an alkyl group.

In formulas (B-7) and (B-11), each R^{X2} independently represents a hydrogen atom or a substituent other than a fluorine atom and perfluoroalkyl groups (e.g., an alkyl group not including a fluorine atom or a cycloalkyl group not including a fluorine atom). Two R^{X2}'s in formula (B-7) may be the same or different.

In formula (B-8), R^{XF1} represents a hydrogen atom, a fluorine atom, or a perfluoroalkyl group, provided that at least one of a plurality of R^{XF1}'s represents a fluorine atom or a perfluoroalkyl group. Two R^{XF1}'s in formula (B-8) may be the same or different. The number of carbon atoms of the perfluoroalkyl group represented by R^{XF1} is preferably 1 to 15, more preferably 1 to 10, still more preferably 1 to 6.

In formula (B-9), R^{X3} represents a hydrogen atom, a halogen atom, or a monovalent organic group. Examples of the halogen atom represented by R^{X3} include a fluorine atom, a chlorine atom, a bromine atom, and an iodine atom, among which a fluorine atom is preferred.

The monovalent organic group represented by R^{X3} is the same as the monovalent organic group described as R^{X1}.

n1 represents an integer of 0 to 4.

n1 is preferably an integer of 0 to 2, preferably 0 or 1. When n1 represents an integer of 2 to 4, a plurality of R^{X3}'s may be the same or different.

In formula (B-10), R^{XF2} represents a fluorine atom or a perfluoroalkyl group.

The number of carbon atoms of the perfluoroalkyl group represented by R^{XF2} is preferably 1 to 15, more preferably 1 to 10, still more preferably 1 to 6.

In formula (DA), the monovalent organic group represented by Rₐ₁ typically, but not necessarily, has 1 to 30 carbon atoms, and preferably has 1 to 20 carbon atoms.

Rₐ₁ is preferably an alkyl group, a cycloalkyl group, or an aryl group.

The alkyl group may be linear or branched, and is preferably an alkyl group having 1 to 20 carbon atoms, more preferably an alkyl group having 1 to 15 carbon atoms, still more preferably an alkyl group having 1 to 10 carbon atoms.

The cycloalkyl group may be monocyclic or polycyclic, and is preferably a cycloalkyl group having 3 to 20 carbon atoms, more preferably a cycloalkyl group having 3 to 15 carbon atoms, still more preferably a cycloalkyl group having 3 to 10 carbon atoms.

The aryl group may be monocyclic or polycyclic, and is preferably an aryl group having 6 to 20 carbon atoms, more preferably an aryl group having 6 to 15 carbon atoms, still more preferably an aryl group having 6 to 10 carbon atoms.

The cycloalkyl group may include a heteroatom as a ring-member atom.

Examples of the heteroatom include, but are not limited to, a nitrogen atom and an oxygen atom.

The cycloalkyl group may include a carbonyl bond (>C═O) as a ring-member atom.

The alkyl group, the cycloalkyl group, and the aryl group may further have a substituent.

A₃₁⁻ and Rₐ₁ may be bonded to each other to form a ring.

The divalent linking group represented by Lai is not particularly limited, and represents an alkylene group, a cycloalkylene group, an aromatic group, —O—, —CO—, —COO—, or a group formed by combining two or more thereof.

The alkylene group may be linear or branched, and preferably has 1 to 20 carbon atoms, more preferably has 1 to 10 carbon atoms.

The cycloalkylene group may be monocyclic or polycyclic, and preferably has 3 to 20 carbon atoms, more preferably has 3 to 10 carbon atoms.

The aromatic group is a divalent aromatic group, and is preferably an aromatic group having 6 to 20 carbon atoms, more preferably an aromatic group having 6 to 15 carbon atoms.

Examples of the aromatic ring constituting the aromatic group include, but are not limited to, aromatic rings having 6 to 20 carbon atoms, specifically, a benzene ring, a naphthalene ring, an anthracene ring, and a thiophene ring. The aromatic ring constituting the aromatic group is preferably a benzene ring or a naphthalene ring, more preferably a benzene ring.

The alkylene group, the cycloalkylene group, and the aromatic group may further have a substituent, and the substituent is preferably a halogen atom.

Lₐ₁ preferably represents a single bond.

As the photodecomposable onium salt compound PG1, for example, photoacid generators disclosed in paragraphs [0135] to [0171] of WO2018/193954A, paragraphs [0077] to [0116] of WO2020/066824A, and paragraphs [0018] to [0075] and [0334] to [0335] of WO2017/154345A are also preferably used.

The molecular weight of the photodecomposable onium salt compound PG1 is preferably 3,000 or less, more preferably 2,000 or less, still more preferably 1,000 or less.

### Photodecomposable Onium Salt Compound PG2

Other preferred examples of the photodecomposable onium salt compound include compounds (I) and (II) described below (hereinafter the “compounds (I) and (II)” are each also referred to as a “photodecomposable onium salt compound PG2”). The photodecomposable onium salt compound PG2 is a compound that has two or more salt structure moieties described above and generates a polyvalent organic acid upon exposure.

Hereinafter, the photodecomposable onium salt compound PG2 will be described.

### Compound (I)

The compound (I) is a compound that has at least one structural moiety X described below and at least one structural moiety Y described below and is a compound that generates, upon irradiation with an actinic ray or a radiation, an acid including a first acidic moiety described below that is derived from the structural moiety X and a second acidic moiety described below that is derived from the structural moiety Y.

Structural moiety X: a structural moiety that is constituted by an anionic moiety A₁⁻ and a cationic moiety M₁⁺ and forms a first acidic moiety expressed as HA₁ upon irradiation with an actinic ray or a radiation

Structural moiety Y: a structural moiety that is constituted by an anionic moiety A₂⁻ and a cationic moiety M₂⁺ and forms a second acidic moiety expressed as HA₂ upon irradiation with an actinic ray or a radiation

The compound (I) satisfies the following condition I.

Condition I: a compound PI, which is derived by replacing the cationic moiety M₁⁺ in the structural moiety X and the cationic moiety M₂⁺ in the structural moiety Y in the compound (I) with H⁺, has an acid dissociation constant a1, which is derived from the acidic moiety derived by replacing the cationic moiety M₁⁺ in the structural moiety X with H⁺ and expressed as HA₁, and an acid dissociation constant a2, which is derived from the acidic moiety derived by replacing the cationic moiety M₂⁺ in the structural moiety Y with H⁺ and expressed as HA₂, and the acid dissociation constant a2 is larger than the acid dissociation constant a1.

The compound PI corresponds to an acid that is generated when the compound (I) is irradiated with an actinic ray or a radiation.

When the compound (I) has two or more structural moieties X, the structural moieties X may be the same as or different from each other. The two or more A₁⁻'s may be the same as or different from each other, and the two or more M₁⁺'s may be the same as or different from each other.

In the compound (I), A₁⁻ and A₂⁻ may be the same as or different from each other, and M₁⁺ and M₂⁺ may be the same as or different from each other. A₁⁻ and A₂⁻ are preferably different from each other.

The anionic moiety A₁⁻ and the anionic moiety A₂⁻ are structural moieties including a negatively charged atom or atomic group, and are, for example, structural moieties selected from the group consisting of formulas (AA-1) to (AA-3) and formulas (BB-1) to (BB-6) shown below. In the following formulas (AA-1) to (AA-3) and formulas (BB-1) to (BB-6), * represents a bonding position. R^{A} represents a monovalent organic group. Examples of the monovalent organic group represented by R^{A} include a cyano group, a trifluoromethyl group, and a methanesulfonyl group.

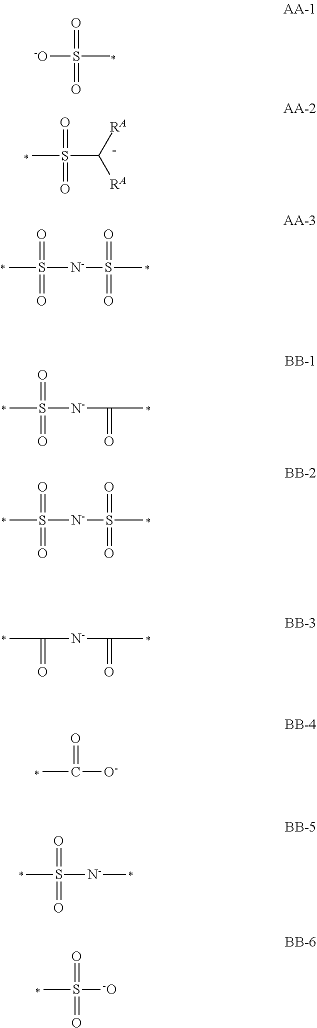

The cationic moiety M₁⁺ and the cationic moiety M₂⁺ are structural moieties including a positively charged atom or atomic group and are, for example, singly charged organic cations. The organic cations are not particularly limited, but are each preferably the organic cation represented by formula (ZaI) (cation (ZaI)) or the organic cation represented by formula (ZaII) (cation (ZaII)) described above.

### Compound (II)

The compound (II) is a compound that has two or more structural moieties X described above and at least one structural moiety Z described below and is a compound that generates, upon irradiation with an actinic ray or a radiation, an acid including the structural moiety Z and two or more first acidic moieties derived from the structural moieties X.

### Structural Moiety Z: A Nonionic Moiety Capable of Neutralizing Acid

The compound (II), upon irradiation with an actinic ray or a radiation, can generate a compound PII (acid) having an acidic moiety derived by replacing the cationic moiety M₁⁺ in the structural moiety X with H⁺ and expressed as HA₁. That is, the compound PII represents a compound having the acidic moiety expressed as HA₁ and the structural moiety Z, which is a nonionic moiety capable of neutralizing acid.

In the compound (II), the definition of the structural moiety X and the definitions of A₁⁻ and M₁⁺ are respectively the same as the definition of the structural moiety X and the definitions of A₁⁻ and M₁⁺ in the compound (I) described above, and preferred embodiments thereof are also the same.

The two or more structural moieties X may be the same as or different from each other. The two or more A₁⁻'s may be the same as or different from each other, and the two or more M₁⁺'s may be the same as or different from each other.

The nonionic moiety capable of neutralizing acid in the structural moiety Z is not particularly limited, and is preferably, for example, a moiety including a functional group having a group or electron that can electrostatically interact with a proton.

The functional group having a group or electron that can electrostatically interact with a proton is, for example, a functional group having a macrocyclic structure such as cyclic polyether or a functional group having a nitrogen atom having an unshared electron pair that does not contribute to x-conjugation. The nitrogen atom having an unshared electron pair that does not contribute to x-conjugation is, for example, a nitrogen atom having a partial structure represented by any of the following formulas.

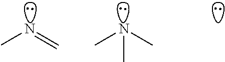

### Unshared Electron Pair

Examples of the partial structure of the functional group having a group or electron that can electrostatically interact with a proton include crown ether structures, azacrown ether structures, primary to tertiary amine structures, a pyridine structure, an imidazole structure, and a pyrazine structure, among which primary to tertiary amine structures are preferred.

The molecular weight of the photodecomposable onium salt compound PG2 is preferably 100 to 10,000, more preferably 100 to 2,500, still more preferably 100 to 1,500.

As the photodecomposable onium salt compound PG2, compounds exemplified in paragraphs [0023] to [0095] of WO2020/158313A can be cited.

Examples of moieties that the photodecomposable onium salt compound PG2 may have and that are other than cations are shown below.

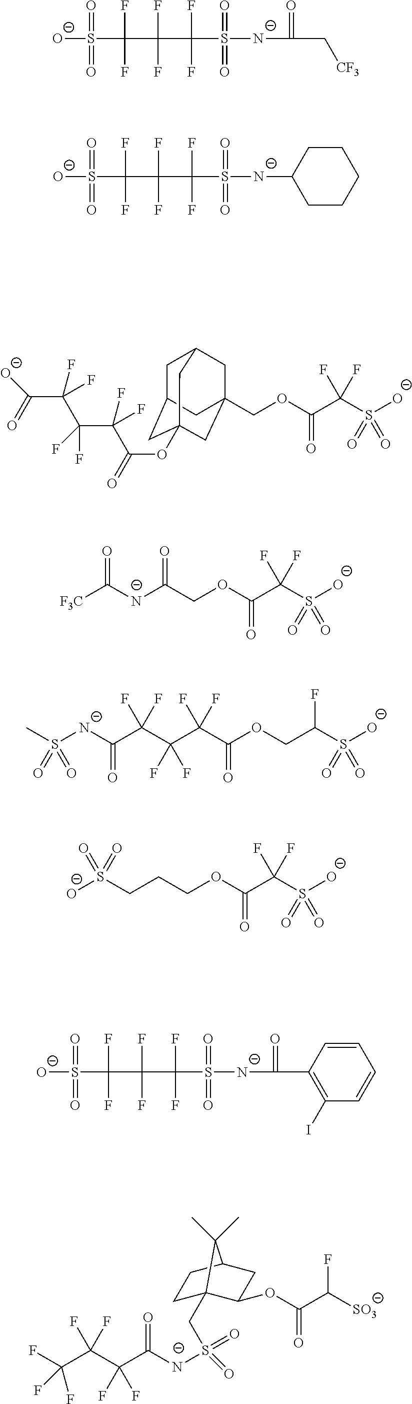

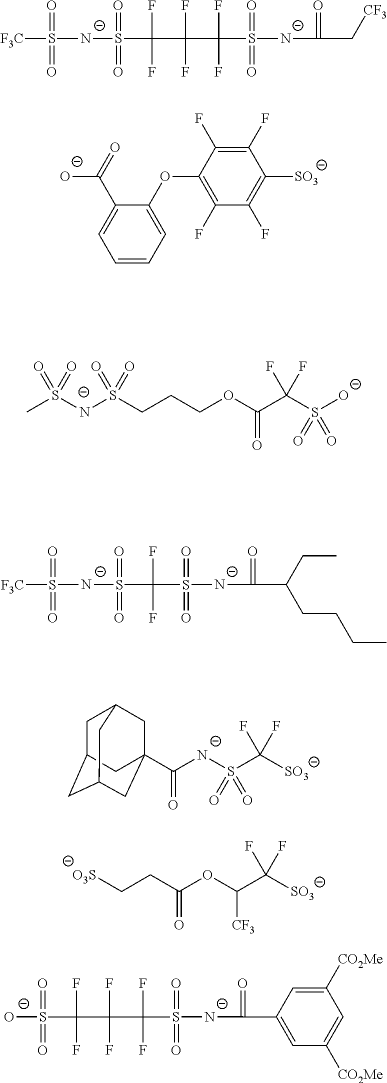

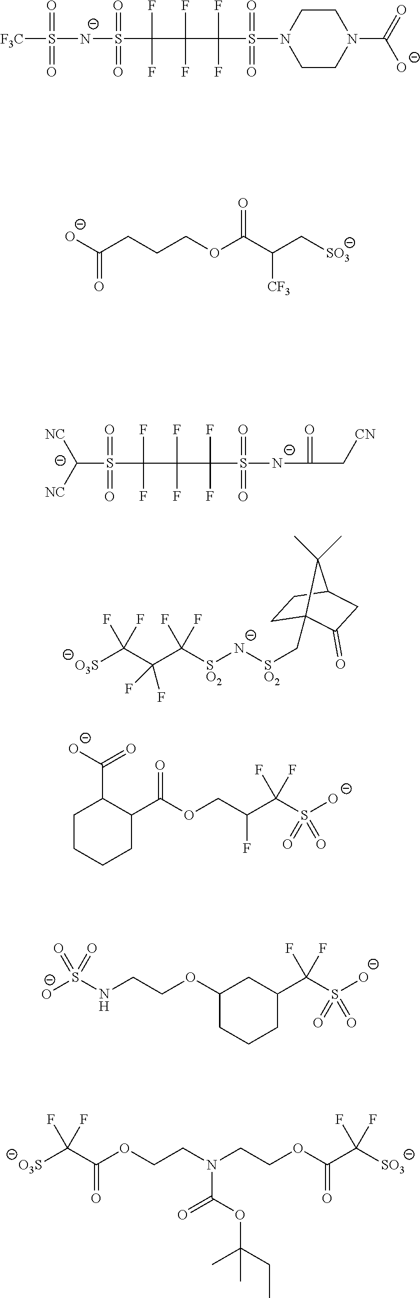

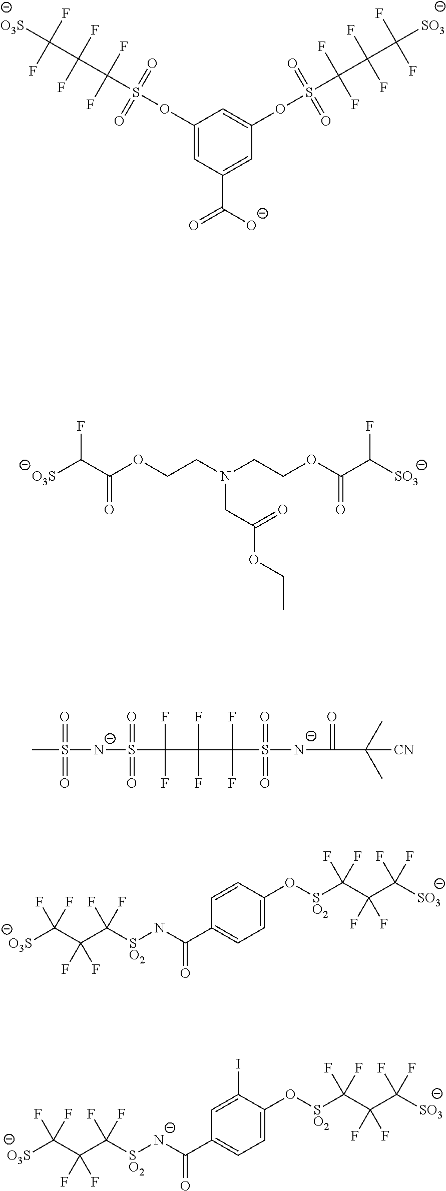

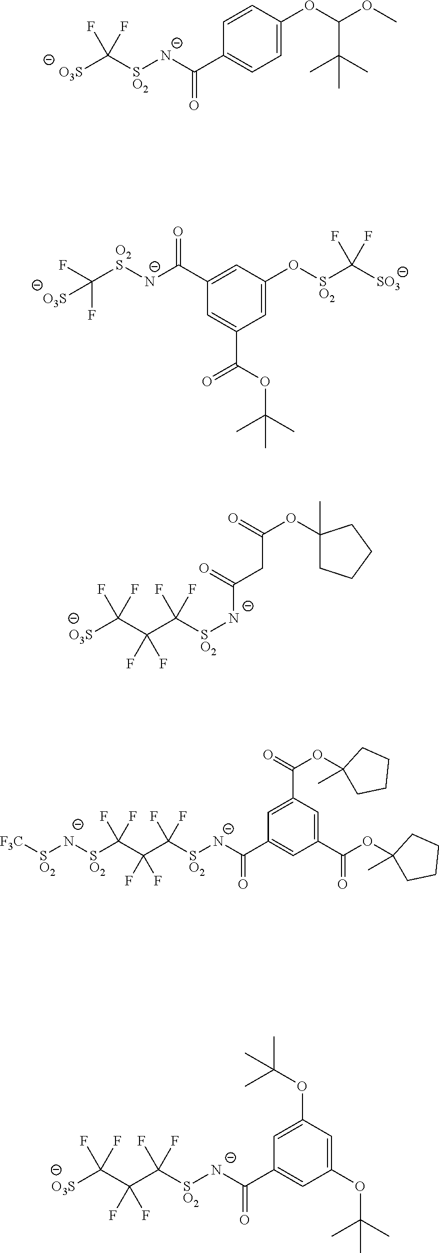

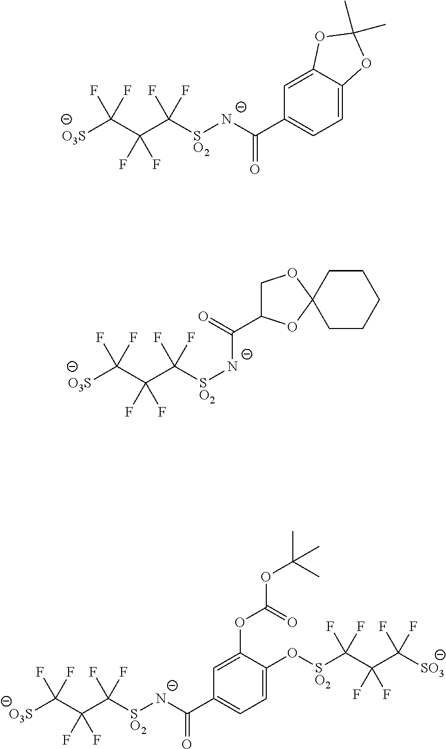

When the resist composition according to the present invention includes the ionic compound (C), the content thereof is not particularly limited, but is preferably 0.5 mass % or more, more preferably 1.0 mass % or more, still more preferably 5.0 mass % or more, relative to the total solid contents of the resist composition. The content is preferably 40.0 mass % or less, more preferably 30.0 mass % or less.

The ionic compound (C) used may be of one single type or two or more types. When two or more types are used, it is preferred that the total content thereof be in the above preferred content range.

### Surfactant

The resist composition according to the present invention may include a surfactant. The presence of a surfactant enables formation of a pattern having higher adhesiveness and less development defects.

The surfactant is preferably a fluorine-based and/or silicon-based surfactant.

Examples of the fluorine-based and/or silicon-based surfactant include surfactants disclosed in paragraphs [0218] and [0219] of WO2018/193954A.

One of these surfactants may be used alone, or two or more of them may be used.

When the resist composition according to the present invention includes a surfactant, the content of the surfactant is preferably 0.0001 to 2 mass %, more preferably 0.0005 to 1 mass %, relative to the total solid contents of the composition.

### Solvent

The resist composition according to the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. The solvent may further include components other than the components (M1) and (M2).

When such a solvent and the resin (B) are used in combination, the coating properties of the resist composition improves, and in addition, a pattern with a smaller number of development defects is readily formed. This is presumably because such a solvent has a good balance of solvency for the resin (B), boiling point, and viscosity and thus can suppress, for example, an uneven film thickness of a resist film that is a composition film of the resist composition and the occurrence of precipitates during spin coating.

The component (M1) is preferably at least one selected from the group consisting of propylene glycol monomethyl ether acetate (PGMEA), propylene glycol monomethyl ether propionate, and propylene glycol monoethyl ether acetate, more preferably propylene glycol monomethyl ether acetate (PGMEA).

The component (M2) is preferably any of the following.

The propylene glycol monoalkyl ether is preferably propylene glycol monomethyl ether (PGME) or propylene glycol monoethyl ether (PGEE).

The lactate is preferably ethyl lactate, butyl lactate, or propyl lactate.

The acetate is preferably methyl acetate, ethyl acetate, butyl acetate, isobutyl acetate, propyl acetate, isoamyl acetate, or 3-methoxybutyl acetate. The formate is preferably methyl formate, ethyl formate, butyl formate, or propyl formate.

Butyl butyrate is also preferred.

The alkoxypropionate is preferably methyl 3-methoxypropionate (MMP) or ethyl 3-ethoxypropionate (EEP).

The chain ketone is preferably 1-octanone, 2-octanone, 1-nonanone, 2-nonanone, acetone, 2-heptanone, 4-heptanone, 1-hexanone, 2-hexanone, diisobutyl ketone, phenyl acetone, methyl ethyl ketone, methyl isobutyl ketone, acetylacetone, acetonylacetone, ionone, diacetonyl alcohol, acetyl carbinol, acetophenone, methyl naphthyl ketone, or methyl amyl ketone.

The cyclic ketone is preferably methylcyclohexanone, isophorone, cyclopentanone, or cyclohexanone.

The lactone is preferably γ-butyrolactone.

The alkylene carbonate is preferably propylene carbonate.

The component (M2) is more preferably propylene glycol monomethyl ether (PGME), ethyl lactate, ethyl 3-ethoxy propionate, methyl amyl ketone, cyclohexanone, butyl acetate, pentyl acetate, γ-butyrolactone, or propylene carbonate.

The solvent also preferably includes, in addition to the above-described components, an ester solvent having 7 or more (preferably 7 to 14, more preferably 7 to 12, still more preferably 7 to 10) carbon atoms and 2 or less heteroatoms.

The ester solvent having 7 or more carbon atoms and 2 or less heteroatoms is preferably amyl acetate, 2-methylbutyl acetate, 1-methylbutyl acetate, hexyl acetate, pentyl propionate, hexyl propionate, butyl propionate, isobutyl isobutyrate, heptyl propionate, or butyl butanoate, more preferably isoamyl acetate.

The component (M2) preferably has a flash point (hereinafter also referred to as fp) of 37° C. or higher. Such a component (M2) is preferably propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.). Of these, propylene glycol monoethyl ether, ethyl lactate, pentyl acetate, and cyclohexanone are more preferred, propylene glycol monoethyl ether and ethyl lactate are still more preferred.

Here, the term “flash point” means a value listed in a reagent catalog of Tokyo Chemical Industry Co., Ltd. or Sigma-Aldrich Co. LLC.

The solvent preferably includes the component (M1). More preferably, the solvent consists substantially of the component (M1) or is a mixed solvent of the component (M1) and other components. In the latter case, the solvent still more preferably includes both the component (M1) and the component (M2).

The mass ratio (M1/M2) of the component (M1) to the component (M2) is preferably in the range of “100/0” to “15/85”, more preferably in the range of “100/0” to “40/60”, still more preferably in the range of “100/0” to “60/40”. In other words, the solvent preferably consists of the component (M1) or includes both the component (M1) and the component (M2) such that their mass ratio is as shown below. That is, in the latter case, the mass ratio of the component (M1) to the component (M2) is preferably 15/85 or more, more preferably 40/60 or more, still more preferably 60/40 or more. When such a configuration is employed, the number of development defects can be further reduced.

When the solvent includes both the component (M1) and the component (M2), the mass ratio of the component (M1) to the component (M2) is, for example, 99/1 or less.

When the solvent further includes components other than the components (M1) and (M2), the content of the components other than the components (M1) and (M2) is preferably 5 to 30 mass % relative to the total amount of the solvent.

For higher coating properties, the content of the solvent in the resist composition according to the present invention is preferably determined such that the concentration of solid contents is 0.5 to 30 mass %, more preferably 1 to 20 mass %.

### Resist Film and Pattern Forming Method

The present invention also relates to a resist film formed of the above-described resist composition.

The procedure of a pattern forming method using the above-described resist composition is not particularly limited, but the method preferably has the following steps.
Step 1: a step of forming a resist film on a substrate using a resist composition
Step 2: a step of exposing the resist film
Step 3: a step of developing the exposed resist film using a developer

Hereinafter, the procedure of each step will be described in detail.

### Step 1: Resist Film Formation Step

The step 1 is a step of forming a resist film on a substrate using a resist composition.

The resist composition in as defined above.

One example of a method of forming a resist film on a substrate using a resist composition is application of the resist composition onto the substrate.

Before the application, the resist composition is preferably filtered through a filter as required. The pore size of the filter is preferably 0.1 μm or less, more preferably 0.05 μm or less, still more preferably 0.03 μm or less. The filter is preferably made of polytetrafluoroethylene, polyethylene, or nylon.

The resist composition can be applied onto a substrate (e.g., silicon, coated with silicon dioxide) as used in manufacturing an integrated circuit element by appropriate application means such as a spinner or a coater. The application means is preferably spin coating using a spinner. The rotational speed in spin coating using a spinner is preferably 1,000 to 3,000 rpm.

After the application of the resist composition, the substrate may be dried to form a resist film. If necessary, various undercoat films (an inorganic film, an organic film, and an antireflection film) may be formed under the resist film.

The method of drying is, for example, drying by heating. The heating can be performed using means provided in an ordinary exposure device and/or an ordinary development device, and may be performed using a hot plate or the like. The heating temperature is preferably 80° C. to 150° C., more preferably 80° C. to 140° C., still more preferably 80° C. to 130° C. The heating time is preferably 30 to 1,000 seconds, more preferably 60 to 800 seconds, still more preferably 60 to 600 seconds.

The film thickness of the resist film is not particularly limited, but to allow formation of a more accurate fine pattern, it is preferably 10 to 120 nm. In particular, in the cases of EUV exposure and EB exposure, the film thickness of the resist film is more preferably 10 to 65 nm, still more preferably 15 to 50 nm. In the case of ArF liquid immersion exposure, the film thickness of the resist film is more preferably 10 to 120 nm, still more preferably 15 to 90 nm.

A topcoat may be formed on the resist film using a topcoat composition.

Preferably, the topcoat composition does not mix with the resist film and further can be uniformly applied on the resist film. The topcoat is not particularly limited, and a topcoat known in the art can be formed by a method known in the art. For example, the topcoat can be formed on the basis of the descriptions in paragraphs to of JP2014-059543A.

For example, it is preferable to form a topcoat including a basic compound as described in JP2013-061648A on the resist film. Specific examples of the basic compound that can be included in the topcoat include basic compounds that may be included in the resist composition.

The topcoat also preferably includes a compound including at least one group or bond selected from the group consisting of an ether bond, a thioether bond, a hydroxyl group, a thiol group, a carbonyl bond, and an ester bond.

### Step 2: Exposure Step

The step 2 is a step of exposing the resist film.

One example of a method of the exposure is irradiation of the formed resist film with an actinic ray or a radiation through a predetermined mask.

Examples of the actinic ray or the radiation include infrared light, visible light, ultraviolet light, far-ultraviolet light, extreme ultraviolet rays, X-rays, and electron beams, the far-ultraviolet light having a wavelength of preferably 250 nm or less, more preferably 220 nm or less, particularly preferably 1 to 200 nm. Specific examples include KrF excimer laser (248 nm), ArF excimer laser (193 nm), F2 excimer laser (157 nm), EUV (13 nm), X-rays, and electron beams.

After the exposure, post-exposure heat treatment (also referred to as post-exposure bake) is preferably performed before development. The post-exposure heat treatment promotes the reaction in exposed portions to provide higher sensitivity and a better pattern profile.

The heating temperature is preferably 80° C. to 150° C., more preferably 80° C. to 140° C., still more preferably 80° C. to 130° C.

The heating time is preferably 10 to 1,000 seconds, more preferably 10 to 180 seconds, still more preferably 30 to 120 seconds.

The heating can be performed using means provided in an ordinary exposure device and/or an ordinary development device, and may be performed using a hot plate or the like.

### Step 3: Development Step

The step 3 is a step of developing the exposed resist film using a developer to form a pattern.

The developer may be an alkali developer or a developer including an organic solvent (hereinafter also referred to as an organic-based developer), and is preferably an organic-based developer.

Examples of methods of the development include immersing the substrate in a tank filled with a developer for a certain period of time (dipping method), forming a puddle of a developer on the surface of the substrate by the action of surface tension and leaving them to stand for a certain period of time to achieve development (puddling method), spraying a developer onto the surface of the substrate (spraying method), and continuously ejecting a developer, while scanning a developer jetting nozzle at a constant rate, onto the substrate rotating at a constant rate (dynamic dispensing method).

After the step of performing development, a step of stopping the development while performing replacement with another solvent may be performed.

The developing time is not particularly limited as long as the resin in unexposed portions is sufficiently dissolved, and is preferably 10 to 300 seconds, more preferably 20 to 120 seconds.

The temperature of the developer is preferably 0° C. to 50° C., more preferably 15° C. to 35° C.

As the alkali developer, an aqueous alkaline solution including an alkali is preferably used. The aqueous alkaline solution may be of any type and is, for example, an aqueous alkaline solution including a quaternary ammonium salt typified by tetramethylammonium hydroxide, an inorganic alkali, a primary amine, a secondary amine, a tertiary amine, an alcohol amine, a cyclic amine, or the like. In particular, the alkali developer is preferably an aqueous solution of a quaternary ammonium salt typified by tetramethylammonium hydroxide (TMAH). An appropriate amount of an alcohol, a surfactant, or the like may be added to the alkali developer. Typically, the alkali developer preferably has an alkali concentration of 0.1 to 20 mass %. Typically, the alkali developer preferably has a pH of 10.0 to 15.0.

The organic-based developer is preferably a developer containing at least one organic solvent selected from the group consisting of ketone solvents, ester solvents, alcohol solvents, amide solvent, ether solvents, and hydrocarbon solvents.

The above solvents may be mixed with each other or may be mixed with a solvent other than the above or water. The developer as a whole has a moisture content of preferably less than 50 mass %, more preferably less than 20 mass %, still more preferably less than 10 mass %, and particularly preferably contains substantially no moisture.

The content of the organic solvent in the organic-based developer is preferably 50 mass % or more and 100 mass % or less, more preferably 80 mass % or more and 100 mass % or less, still more preferably 90 mass % or more and 100 mass % or less, particularly preferably 95 mass % or more and 100 mass % or less, relative to the total amount of the developer.

### Other Steps

The pattern forming method preferably includes, after the step 3, a step of performing washing using a rinsing liquid.

The rinsing liquid for use in the rinsing step after the development step using an alkali developer is, for example, pure water. An appropriate amount of surfactant may be added to the pure water.

An appropriate amount of surfactant may be added to the rinsing liquid.

The rinsing liquid for use in the rinsing step after the development step using an organic-based developer is not particularly limited as long as it does not dissolve the pattern, and a solution including a commonly used organic solvent can be used. The rinsing liquid for use is preferably a rinsing liquid containing at least one organic solvent selected from the group consisting of hydrocarbon solvents, ketone solvents, ester solvents, alcohol solvents, amide solvents, and ether solvents.

Examples of methods of the rinsing step include, but are not limited to, continuously ejecting the rinsing liquid onto the substrate rotating at a constant rate (spin-coating method), immersing the substrate in a tank filled with the rinsing liquid for a certain period of time (dipping method), and spraying the rinsing liquid onto the surface of the substrate (spraying method).

The pattern forming method according to the present invention may include a heating step (post bake) after the rinsing step. In this step, the developer and the rinsing liquid remaining between and within patterns are removed by baking. In addition, this step also has an effect of annealing the resist pattern to improve the surface roughness of the pattern. The heating step after the rinsing step is performed typically at 40° C. to 250° C. (preferably 90° C. to 200° C.) typically for 10 seconds to 3 minutes (preferably 30 seconds to 120 seconds).

The pattern formed may be used as a mask to perform etching treatment on the substrate. Specifically, the pattern formed in the step 3 may be used as a mask to process the substrate (or an underlayer film and the substrate), thereby forming a pattern on the substrate.

The method of processing the substrate (or an underlayer film and the substrate) is not particularly limited, but a preferred method is to perform dry etching on the substrate (or an underlayer film and the substrate) using the pattern formed in the step 3 as a mask, thereby forming a pattern on the substrate. The dry etching is preferably oxygen plasma etching.

The resist composition and various materials used in the pattern forming method according to the present invention (e.g., solvents, developers, rinsing liquids, compositions for antireflection film formation, and compositions for topcoat formation) are preferably free of impurities such as metals. The content of impurities included in these materials is preferably 1 mass ppm or less, more preferably 10 mass ppb or less, still more preferably 100 mass ppt or less, particularly preferably 10 mass ppt or less, most preferably 1 mass ppt or less. Examples of metal impurities include Na, K, Ca, Fe, Cu, Mg, Al, Li, Cr, Ni, Sn, Ag, As, Au, Ba, Cd, Co, Pb, Ti, V, W, and Zn.

One example of a method of removing impurities such as metals from the various materials is filtration using a filter. Details of the filtration using a filter are described in paragraph [0321] of WO2020/004306A.

Examples of methods of reducing the amount of impurities such as metals included in the various materials include selecting raw materials with low metal contents as raw materials constituting the various materials, performing filter filtration on raw materials constituting the various materials, and performing distillation under conditions where contamination is minimized by, for example, lining the inside of an apparatus with Teflon (registered trademark).

Instead of filter filtration, an adsorbent may be used to remove impurities, or filter filtration and an adsorbent may be used in combination. The adsorbent may be a known adsorbent, and, for example, inorganic-based adsorbents such as silica gel and zeolite and organic-based adsorbents such as activated carbon can be used. To reduce the amount of impurities such as metals included in the various materials, entry of metal impurities during the production process needs to be prevented. Whether metal impurities are sufficiently removed from a production apparatus can be determined by measuring the content of metal components included in a washing solution used to wash the production apparatus. The content of metal components included in the used washing solution is preferably 100 mass ppt (parts per trillion) or less, more preferably 10 mass ppt or less, still more preferably 1 mass ppt or less.

The resist composition may include water as an impurity. When water is included as an impurity, the content of the water is preferably as low as possible and may be 1 to 30,000 mass ppm relative to the total amount of the resist composition.

The resist composition may also include residual monomers (e.g., monomers derived from starting monomers used to synthesize the resin) as impurities. When residual monomers are included as impurities, the content of the residual monomers is preferably as low as possible and may be 1 to 30,000 mass ppm relative to the total solid contents of the resist composition.

To organic-based treatment liquids such as the rinsing liquid, a conductive compound may be added in order to prevent failure of chemical liquid pipes and various parts (e.g., a filter, an O-ring, and a tube), which might otherwise be caused by electrostatic buildup and subsequent electrostatic discharging. One non-limiting example of the conductive compound is methanol. The amount of addition is not particularly limited, but is preferably 10 mass % or less, more preferably 5 mass % or less, from the viewpoint of maintaining preferred developing performance or rinsing performance.

The chemical liquid pipes may be, for example, various pipes made of SUS (stainless steel) or coated with polyethylene, polypropylene, or a fluorocarbon resin (e.g., polytetrafluoroethylene or a perfluoroalkoxy resin) subjected to antistatic treatment. Similarly for the filter and the O-ring, polyethylene, polypropylene, or a fluorocarbon resin (e.g., polytetrafluoroethylene or a perfluoroalkoxy resin) subjected to antistatic treatment can be used.

### Method for Producing Electronic Device

The present invention also relates to a method for producing an electronic device, the method including the above-described pattern forming method, and an electronic device produced by the production method.

The electronic device according to the present invention is suitably mounted on electric or electronic equipment (e.g., household appliances, office automation (OA), media-related equipment, optical equipment, and communication equipment).

### Examples

The present invention will now be described in more detail with reference to Examples. The materials, amounts used, ratios, treatment details, treatment procedures, etc. given in the following Examples may be changed as appropriate without departing from the spirit of the present invention. Thus, the scope of the present invention should not be construed as being limited by the Examples given below.

### Various Components of Actinic Ray-Sensitive or Radiation-Sensitive Resin Composition

### Metal Compound (A)

The structures of metal compounds (A-1 to A-4) listed in Table 1 are shown below.

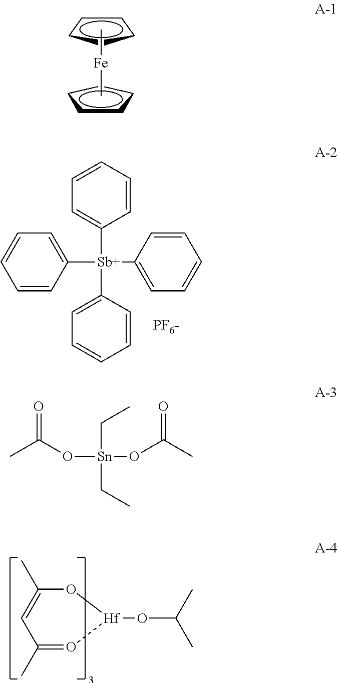

### Resin (B)

Resins (B-1 to B-22 and RB-1 to RB-4) listed in Table 1 were synthesized by known methods. Resins RB-1 to RB-4 correspond to resins for comparison.

The structures of resins B-1 to B-22 and RB-1 to RB-4 listed in Table 1 are shown below.

In the following resins, the composition ratio of each repeating unit is expressed in units of mol %.

The weight-average molecular weight (Mw) and the dispersity (Mw/Mn) of resins B-1 to B-22 and RB-1 to RB-4 were measured by GPC (carrier: tetrahydrofuran (THF)) (in terms of polystyrene amount). The composition ratio (mol % ratio) of the resins was measured by ¹³C-NMR (nuclear magnetic resonance).

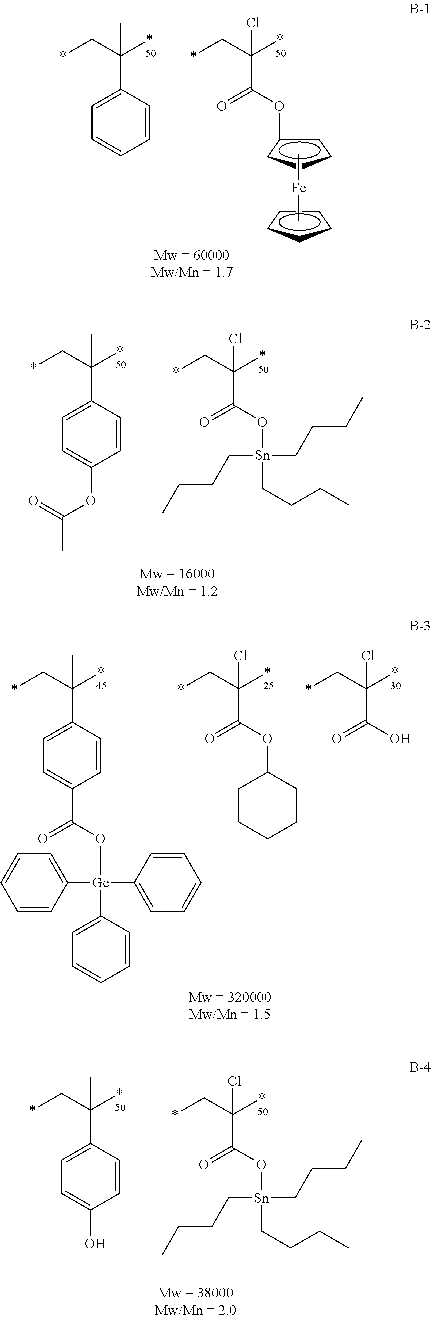

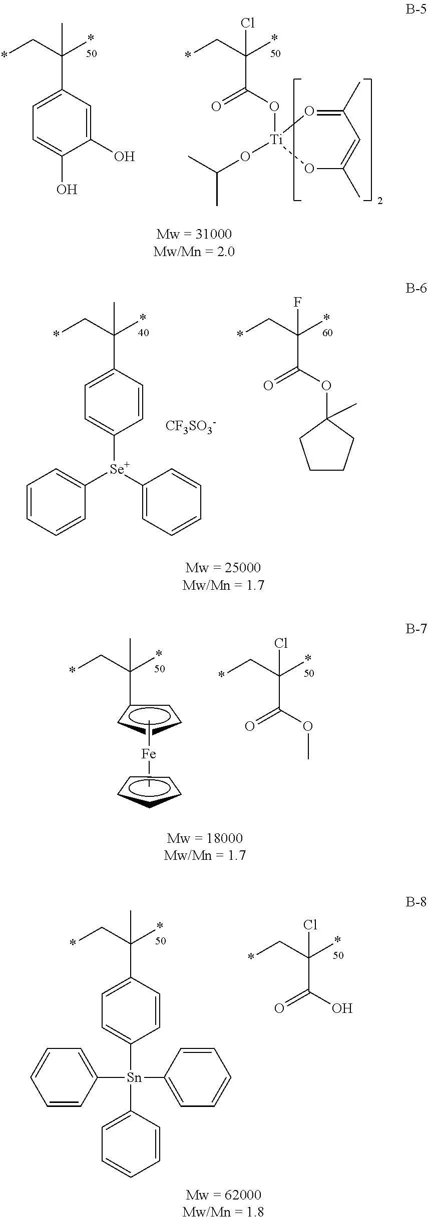

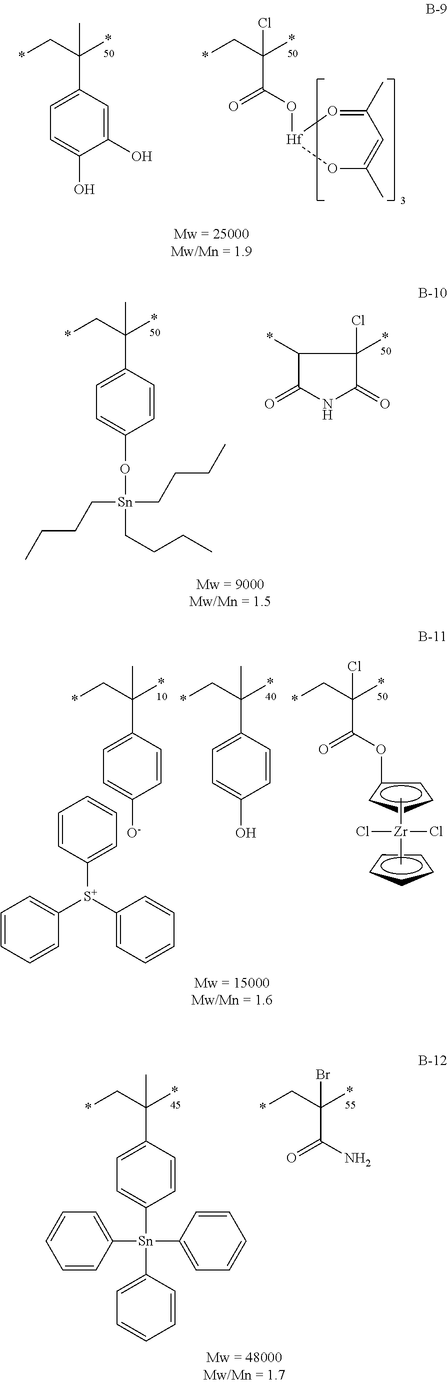

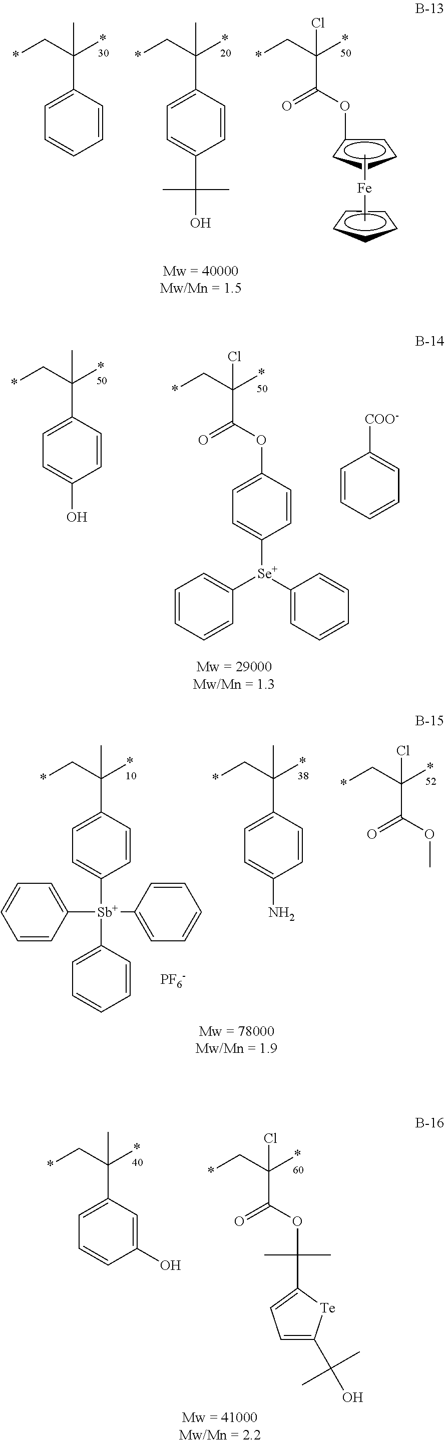

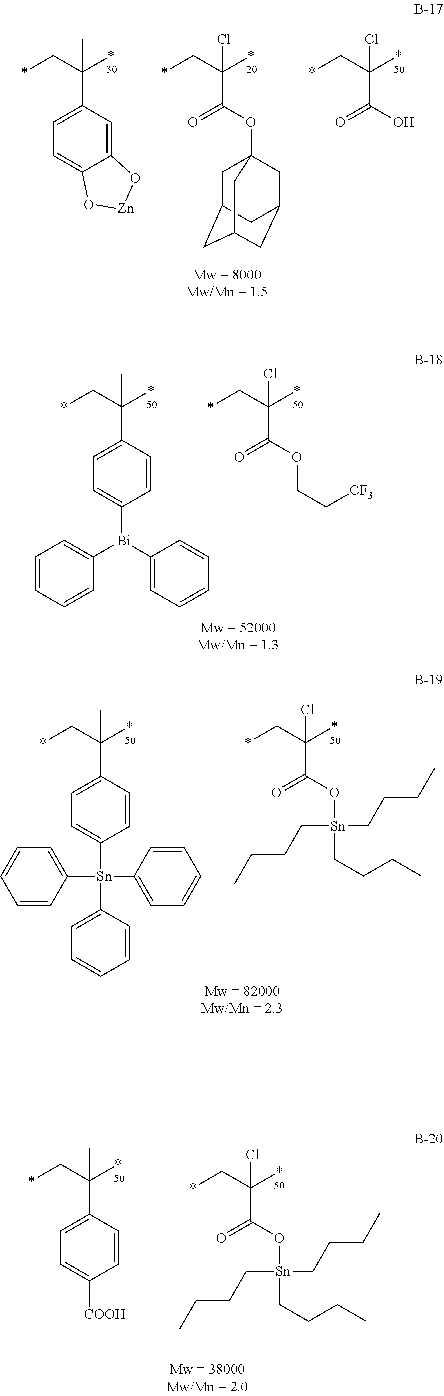

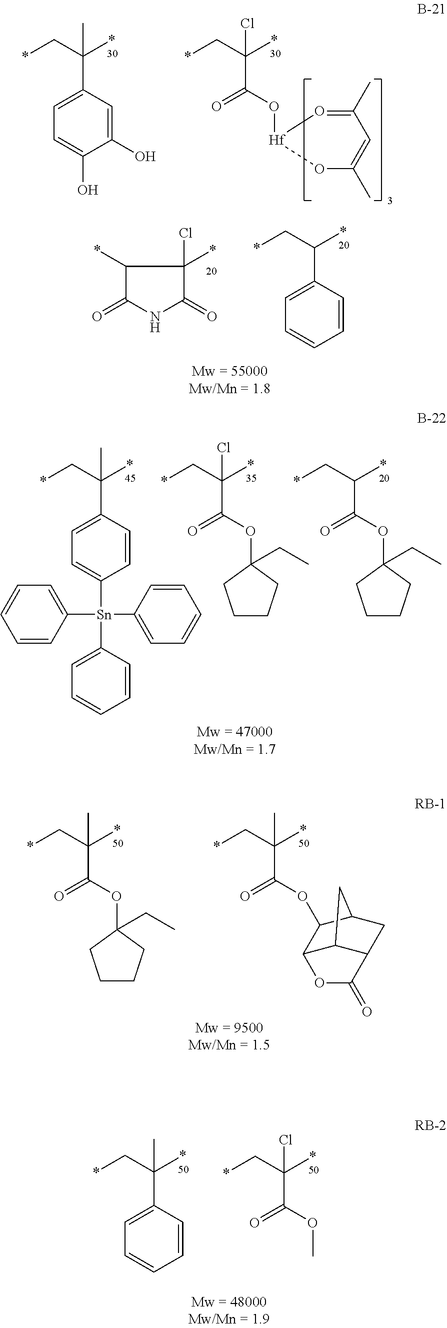

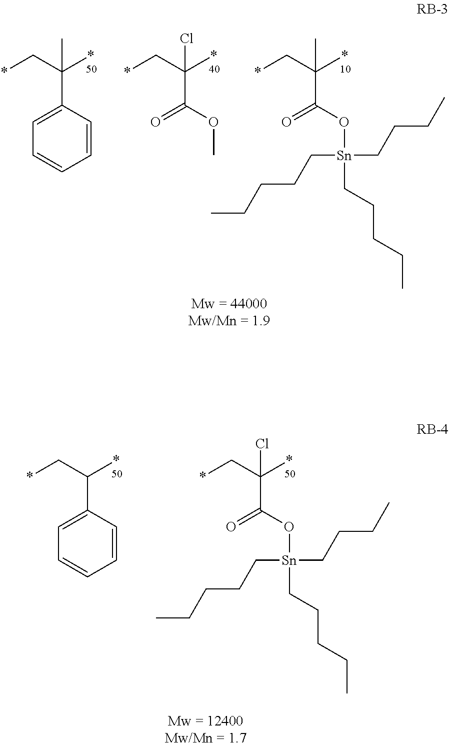

### Ionic Compound (C)

The structures of ionic compounds (C-1 to C-5) listed in Table 1 are shown below. Ionic compounds (C-1 to C-5) each correspond to a photodecomposable onium salt compound.

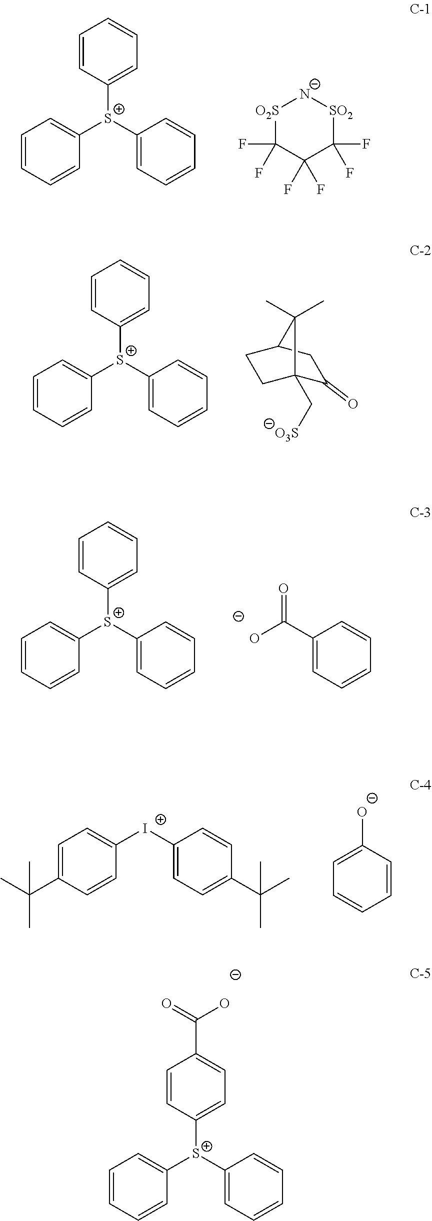

### Solvent (D)

Solvents listed in Table 1 are shown below.
D-1: propylene glycol monomethyl ether acetate (PGMEA)
D-2: propylene glycol monomethyl ether (PGME)
D-3: cyclohexanone
D-4: ethyl lactate
D-5: γ-butyrolactone
D-6: diacetone alcohol

### Preparation of Actinic Ray-Sensitive or Radiation-Sensitive Resin Composition

The components shown in Table 1 were dissolved in the solvents shown in Table 1 to prepare solutions whose concentration of solid contents was 2.0 mass %, and the solutions were each filtered through a polyethylene filter having a pore size of 0.02 μm to prepare resist compositions.

Solid contents mean all components other than solvents. The resist compositions obtained were used in Examples and Comparative Examples.

In the table, the “Mass %” columns show the content (mass %) of each component relative to the total solid contents in each resist composition. In addition, the table shows the type of solvents used and their mass ratio.

Each resist composition included, as impurities, monomers derived from starting monomers used to synthesize the resin (B) in an amount of 1 to 30,000 mass ppm relative to the total solid contents of the resist composition.

TABLE 1

| | Metal | | | | Ionic | | | |
|---|---|---|---|---|---|---|---|---|
| | compound (A) | | Resin (B) | | compound (C) | | Solvent (D) | |
| Composition | Type | Mass % | Type | Mass % | Type | Mass % | Type | Mass ratio |
| R-1 | A-1 | 10 | B-1 | 80 | C-2 | 10 | D-1/D-2 | 80/20 |
| R-2 | — | — | B-2 | 100 | — | — | D-1/D-2 | 70/30 |
| R-3 | — | — | B-3 | 100 | — | — | D-1/D-2/D-5 | 70/25/5 |
| R-4 | — | — | B-4 | 80 | C-1 | 20 | D-1/D-2 | 80/20 |
| R-5 | — | — | B-5 | 100 | — | — | D-1/D-2 | 40/60 |
| R-6 | — | — | B-6 | 100 | — | — | D-1/D-2/D-5 | 80/10/10 |
| R-7 | — | — | B-7 | 90 | C-1 | 10 | D-1/D-2 | 70/30 |
| R-8 | — | — | B-8 | 85 | C-1 | 15 | D-1/D-3 | 90/10 |
| R-9 | A-4 | 10 | B-9 | 90 | — | — | D-1/D-6 | 50/50 |
| R-10 | A-3 | 20 | B-10 | 80 | — | — | D-1/D-2 | 80/20 |
| R-11 | — | — | B-11 | 95 | C-3 | 5 | D-1/D-2 | 70/30 |
| R-12 | — | — | B-12 | 90 | C-3 | 10 | D-1/D-2 | 70/30 |
| R-13 | — | — | B-13 | 85 | C-4 | 15 | D-1/D-2 | 80/20 |
| R-14 | — | — | B-14 | 100 | — | — | D-1/D-2 | 70/30 |
| R-15 | A-2 | 15 | B-15 | 85 | — | — | D-1/D-2 | 70/30 |
| R-16 | — | — | B-16 | 100 | — | — | D-1/D-2 | 70/30 |
| R-17 | — | — | B-17 | 90 | C-5 | 10 | D-1/D-4 | 80/20 |
| R-18 | A-1 | 10 | B-18 | 80 | C-2 | 10 | D-1/D-2 | 80/20 |
| R-19 | — | — | B-19 | 100 | — | — | D-1/D-2 | 80/20 |
| R-20 | — | — | B-20 | 100 | — | — | D-1/D-2 | 80/20 |
| R-21 | — | — | B-21 | 100 | — | — | D-1/D-2 | 80/20 |
| R-22 | — | — | B-22 | 80 | C-3 | 20 | D-1/D-2 | 80/20 |
| RX-1 | — | — | RB-1 | 80 | C-1 | 20 | D-1/D-2 | 80/20 |
| RX-2 | — | — | RB-2 | 100 | — | — | D-1/D-2 | 70/30 |
| RX-3 | — | — | RB-3 | 100 | — | — | D-1/D-2 | 80/20 |
| RX-4 | — | — | RB-4 | 100 | — | — | D-1/D-2 | 80/20 |

### Pattern Forming Method and Evaluation

### Pattern Forming Method Using EUV Exposure and Evaluation: Examples 1-1 to 1-22 and Comparative Examples 1-1 to 1-4

### Pattern Formation

A composition for underlayer film formation AL412 (manufactured by Brewer Science, Inc.) was applied onto a silicon wafer and baked at 205° C. for 60 seconds to form an undercoat film having a film thickness of 20 nm. A freshly produced resist composition shown in Table 2 was applied thereonto and baked at 100° C. for 60 seconds to form a resist film having a film thickness of 30 nm.

The resulting resist-film-carrying silicon wafer was subjected to pattern exposure using an EUV exposure apparatus (Micro Exposure Tool manufactured by Exitech Ltd.; NA, 0.3; Quadrupol; outer sigma, 0.68; inner sigma, 0.36). As a reticle, a mask having a line size of 20 nm and a line-to-space ratio of 1:1 was used.

After the exposed resist film was baked at 100° C. for 60 seconds, development was performed by puddling for 30 seconds with a developer shown in Table 2, and only if stated, a rinsing liquid shown in Table 2 below was poured over for 10 seconds to perform rinsing while the wafer was rotated at a rotational speed of 1,000 rpm, after which the wafer was rotated at a rotational speed of 4,000 rpm for 30 seconds to thereby obtain a line-and-space pattern with a pitch of 40 nm.

### Evaluation

### Optimum Exposure Dose

Using a critical dimension scanning electron microscope (SEM, CG-4100 manufactured by Hitachi High-Tech Corporation), the line width of the line-and-space pattern was measured at various exposure doses, and an exposure dose at which the line width was 20 nm was determined as an optimum exposure dose (mJ/cm²).

Smaller optimum exposure doses indicate higher sensitivity.

The resolution was also evaluated in the following manner.

### Resolution

Under the above exposure and development conditions for the formation of a resist pattern, an exposure dose at which a mask pattern with a line width of 20 nm was reproduced was determined as an optimum exposure dose, and the exposure dose was further increased from the optimum exposure dose so that line-and-space patterns having smaller line widths were formed. In this process, a marginal minimum line width at which resolution was achieved without breakage of a pattern was determined as a resolution-indicating value (nm). Smaller resolution-indicating values represent that finer patterns are resolved and indicate higher resolving power. More specifically, the resolution is preferably 17 nm or less, more preferably 16 nm or less, still more preferably 15 nm or less.

The results obtained are shown in Table 2.

TABLE 2

| | | | | Evaluation | |
|---|---|---|---|---|---|
| | | | | Optimum | |
| | | | | exposure | Reso- |
| | | | Rinsing | dose | lution |
| Table 2 | Composition | Developer | liquid | [mJ/cm²] | [nm] |
| Example 1-1 | R-1 | E-1 | — | 50 | 18 |
| Example 1-2 | R-2 | E-1 | E-3 | 45 | 16 |
| Example 1-3 | R-3 | E-2 | — | 50 | 15 |
| Example 1-4 | R-4 | E-1 | E-3 | 45 | 14 |
| Example 1-5 | R-5 | E-2 | E-3 | 45 | 15 |
| Example 1-6 | R-6 | E-1 | — | 60 | 18 |
| Example 1-7 | R-7 | E-1 | E-3 | 45 | 18 |
| Example 1-8 | R-8 | E-2 | — | 50 | 14 |
| Example 1-9 | R-9 | E-1 | E-3 | 65 | 15 |
| Example 1-10 | R-10 | E-1 | — | 50 | 16 |
| Example 1-11 | R-11 | E-1 | E-3 | 50 | 14 |
| Example 1-12 | R-12 | E-3 | — | 65 | 16 |
| Example 1-13 | R-13 | E-1 | — | 45 | 16 |
| Example 1-14 | R-14 | E-3 | E-4 | 50 | 15 |
| Example 1-15 | R-15 | E-1 | — | 50 | 16 |
| Example 1-16 | R-16 | E-3 | — | 45 | 15 |
| Example 1-17 | R-17 | E-1 | E-3 | 50 | 15 |
| Example 1-18 | R-18 | E-1 | E-3 | 50 | 18 |
| Example 1-19 | R-19 | E-1 | E-3 | 45 | 18 |
| Example 1-20 | R-20 | E-1 | — | 45 | 15 |
| Example 1-21 | R-21 | E-1 | E-3 | 60 | 15 |
| Example 1-22 | R-22 | E-1 | — | 65 | 18 |
| Comparative | RX-1 | E-1 | E-3 | not | not |
| Example 1-1 | | | | resolved | resolved |
| Comparative | RX-2 | E-1 | E-3 | 80 | 20 |
| Example 1-2 | | | | | |
| Comparative | RX-3 | E-3 | E-3 | 70 | 18 |
| Example 1-3 | | | | | |
| Comparative | RX-4 | E-3 | E-3 | not | not |
| Example 1-4 | | | | resolved | resolved |

Developers and rinsing liquids shown in Table 2 above and Table 3 below are as follows.
E-1: butyl acetate
E-2: isopropyl acetate
E-3: butyl acetate:n-undecane=90:10 (mass ratio)
E-4:4-methyl-2-pentanol

### Pattern Forming Method Using EB Exposure and Evaluation: Examples 2-1 to 2-22 and Comparative Examples 2-1 to 2-4

### Pattern Formation

Using an ACTM (manufactured by Tokyo Electron Limited), a composition for antireflection film formation DUV44 (manufactured by Brewer Science, Inc.) was applied onto a 152-mm square mask blank having a Cr outermost surface and baked at 205° C. for 60 seconds to form an underlayer film having a film thickness of 60 nm.

A freshly produced resist composition shown in Table 3 was applied and baked at 100° C. for 60 seconds to form a resist film having a film thickness of 30 nm. Thus, a resist-film-carrying mask blank was formed.

The resist-film-carrying mask blank obtained by the above procedure was subjected to pattern irradiation using an electron beam exposure device (EBM-9000 manufactured by NuFlare Technology Inc.; acceleration voltage, 50 kV). At this time, the patterning was performed so as to form a line and space with a line size of 22 nm and in a ratio of 1:1.

After the exposed resist film was baked at 100° C. for 60 seconds, development was performed by puddling for 30 seconds with a developer shown in Table 3, and only if stated, a rinsing liquid shown in Table 3 below was poured over for 10 seconds to perform rinsing while the wafer was rotated at a rotational speed of 1,000 rpm, after which the wafer was rotated at a rotational speed of 4,000 rpm for 30 seconds to thereby obtain a line-and-space pattern with a pitch of 44 nm.

### Evaluation

The optimum exposure dose and the resolution were evaluated by the following methods.

### Optimum Exposure Dose

Using a critical dimension scanning electron microscope (SEM, CG-4100 manufactured by Hitachi High-Tech Corporation), the line width of the line-and-space pattern was measured at various exposure doses, and an exposure dose at which the line width was 22 nm was determined as an optimum exposure dose (μC/cm²).

Smaller optimum exposure doses indicate higher sensitivity.

The resolution was also evaluated in the following manner.

### Resolution

Under the above exposure and development conditions for the formation of a resist pattern, an exposure dose at which a mask pattern with a line width of 22 nm was reproduced was determined as an optimum exposure dose, and the exposure dose was further increased from the optimum exposure dose so that line-and-space patterns having smaller line widths were formed. In this process, a marginal minimum line width at which resolution was achieved without breakage of a pattern was determined as a resolution-indicating value (nm). Smaller resolution-indicating values represent that finer patterns are resolved and indicate higher resolving power. More specifically, the resolution is preferably 20 nm or less, more preferably 18 nm or less, still more preferably 16 nm or less.

In Comparative Example 2-2, since a mask pattern having a line width of 22 nm could not be formed, an exposure dose at which a mask pattern with a line width of 30 nm was reproduced was determined as an optimum exposure dose.

The results obtained are shown in Table 3.

TABLE 3

| | | | | Evaluation | |
|---|---|---|---|---|---|
| | | | | Optimum | |
| | | | | exposure | Reso- |
| | | | Rinsing | dose | lution |
| Table 3 | Composition | Developer | liquid | [μC/cm²] | [nm] |
| Example 2-1 | R-1 | E-1 | — | 280 | 22 |
| Example 2-2 | R-2 | E-1 | E-3 | 260 | 20 |
| Example 2-3 | R-3 | E-2 | — | 250 | 16 |
| Example 2-4 | R-4 | E-1 | E-3 | 280 | 18 |
| Example 2-5 | R-5 | E-2 | E-3 | 260 | 18 |
| Example 2-6 | R-6 | E-1 | — | 330 | 22 |
| Example 2-7 | R-7 | E-1 | E-3 | 270 | 20 |
| Example 2-8 | R-8 | E-2 | — | 280 | 16 |
| Example 2-9 | R-9 | E-1 | E-3 | 350 | 18 |
| Example 2-10 | R-10 | E-1 | — | 280 | 20 |
| Example 2-11 | R-11 | E-1 | E-3 | 290 | 18 |
| Example 2-12 | R-12 | E-3 | — | 320 | 20 |
| Example 2-13 | R-13 | E-1 | — | 290 | 20 |
| Example 2-14 | R-14 | E-3 | E-4 | 290 | 18 |
| Example 2-15 | R-15 | E-1 | — | 270 | 20 |
| Example 2-16 | R-16 | E-3 | — | 260 | 18 |
| Example 2-17 | R-17 | E-1 | E-3 | 260 | 18 |
| Example 2-18 | R-18 | E-1 | E-3 | 260 | 22 |
| Example 2-19 | R-19 | E-1 | E-3 | 250 | 22 |
| Example 1-20 | R-20 | E-1 | — | 260 | 18 |
| Example 1-21 | R-21 | E-1 | E-3 | 320 | 18 |
| Example 1-22 | R-22 | E-1 | — | 330 | 20 |
| Comparative | RX-1 | E-1 | E-3 | not | not |
| Example 2-1 | | | | resolved | resolved |
| Comparative | RX-2 | E-1 | E-3 | 450 | 26 |
| Example 2-2 | | | | | |
| Comparative | RX-3 | E-3 | E-3 | 380 | 22 |
| Example 2-3 | | | | | |
| Comparative | RX-4 | E-3 | E-3 | not | not |
| Example 2-4 | | | | resolved | resolved |

It has been found from Tables 2 and 3 that the resist compositions used in Examples have high sensitivity in pattern formation.

It has also been found that when the resin (B) has an interactive group, higher resolution is provided.

### Dry Etching Resistance Evaluation: Examples 3-1 to 3-22 and Comparative Examples 3-1 to 3-4

The resist compositions shown in Table 4 were each applied to a silicon wafer and baked at 130° C. for 60 seconds to form resist films having a film thickness of 80 nm. The thickness X0 (nm) of the resist films was measured.

Subsequently, using a Tactras Vigas (manufactured by Tokyo Electron Limited), etching was performed under the following etching conditions.
Etching gas: Ar/CHCl₃=4/1
Pressure: 20 m Torr
Application Pw: 100 mW/cm²
Etching time: 60 s

The thickness X1 (nm) of the etched resist films was measured. Etching rate=(X0−X1)/60 (nm/s) was calculated, and the dry etching resistance was evaluated according to the following criteria. Smaller etching rates indicate higher dry etching resistance.

A: The etching rate is less than 1.3 nm/s.

B: The etching rate is 1.3 nm/s or more and less than 1.8 nm/s.

C: The etching rate is 1.8 nm/s or more and less than 2.3 nm/s.

D: The etching rate is 2.3 nm/s or more.

The results obtained are shown in Table 4.

TABLE 4

| Table 4 | Composition | Etching resistance |
|---|---|---|
| Example 3-1 | R-1 | A |
| Example 3-2 | R-2 | A |
| Example 3-3 | R-3 | A |
| Example 3-4 | R-4 | A |
| Example 3-5 | R-5 | A |
| Example 3-6 | R-6 | B |
| Example 3-7 | R-7 | B |
| Example 3-8 | R-8 | A |
| Example 3-9 | R-9 | A |
| Example 3-10 | R-10 | A |
| Example 3-11 | R-11 | A |
| Example 3-12 | R-12 | A |
| Example 3-13 | R-13 | A |
| Example 3-14 | R-14 | A |
| Example 3-15 | R-15 | C |
| Example 3-16 | R-16 | A |
| Example 3-17 | R-17 | B |
| Example 3-18 | R-18 | A |
| Example 3-19 | R-19 | A |
| Example 3-20 | R-20 | A |
| Example 3-21 | R-21 | B |
| Example 3-22 | R-22 | B |
| Comparative | RX-1 | D |
| Example 3-1 | | |
| Comparative | RX-2 | D |
| Example 3-2 | | |
| Comparative | RX-3 | C |
| Example 3-3 | | |
| Comparative | RX-4 | A |
| Example 3-4 | | |

It has been found from Table 4 that the presence of a metal-containing group in the resin (B) provides higher etching resistance, and when the content of a repeating unit having a metal-containing group in the resin (B) is high, even higher etching resistance is provided.

According to the present invention, an actinic ray-sensitive or radiation-sensitive resin composition having high sensitivity, a resist film, a pattern forming method, and a method for producing an electronic device, the method including the pattern forming method, can be provided.

While the invention has been described in detail with reference to specific embodiments, it will be apparent to those skilled in the art that various changes and modifications can be made without departing from the spirit and scope of the invention.

What is claimed is:

1. An actinic ray-sensitive or radiation-sensitive resin composition comprising a resin including a repeating unit represented by formula (1) below and a repeating unit represented by formula (2) below, 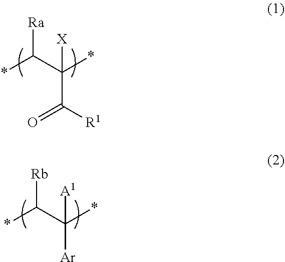
wherein, in formula (1), X represents a halogen atom, a fluorinated alkyl group, or a fluorinated cycloalkyl group,
Ra represents a hydrogen atom or a substituent,
R¹ represents a substituent, and R¹ and Ra may be bonded to each other to form a ring, and
in formula (2), A¹ represents an optionally substituted alkyl group or cycloalkyl group,
Rb represents a hydrogen atom or a substituent,
Ar represents an aromatic hydrocarbon group or a metal complex group, and
Ar and Rb may be bonded to each other to form a ring,
provided that at least one of the repeating unit represented by formula (1) or the repeating unit represented by formula (2) has a group derived from at least one metal compound selected from the group consisting of a metal complex, an organometallic salt, an inorganic metal compound, and an organometallic compound.

2. The actinic ray-sensitive or radiation-sensitive resin composition according to claim 1, wherein the resin includes at least one functional group selected from the group consisting of a hydroxyl group, a carboxyl group, an amino group, an amide group, an imide group, a thiol group, an acetyl group, and an acetoxy group.

3. The actinic ray-sensitive or radiation-sensitive resin composition according to claim 1, wherein the resin includes at least one functional group selected from the group consisting of a phenolic hydroxyl group and a carboxyl group.

4. The actinic ray-sensitive or radiation-sensitive resin composition according to claim 1, wherein X in formula (1) above represents a chlorine atom.

5. The actinic ray-sensitive or radiation-sensitive resin composition according to claim 1, wherein the group derived from the at least one metal compound comprises at least one metal atom selected from the group consisting of an iron atom, a titanium atom, a tin atom, a selenium atom, a zirconium atom, a zinc atom, a bismuth atom, a germanium atom, and a hafnium atom.

6. The actinic ray-sensitive or radiation-sensitive resin composition according to claim 1, further comprising a photodecomposable onium salt compound.

7. The actinic ray-sensitive or radiation-sensitive resin composition according to claim 1, further comprising at least one metal compound selected from the group consisting of a metal complex, an organometallic salt, and an organometallic compound.

8. A resist film formed from the actinic ray-sensitive or radiation-sensitive resin composition according to claim 1.

9. A pattern forming method comprising:
forming a resist film on a substrate using the actinic ray-sensitive or radiation-sensitive resin composition according to claim 1;
exposing the resist film; and
developing the exposed resist film using a developer.

10. A method for producing an electronic device, the method comprising the pattern forming method according to claim 9.
